(19) United States
(12) Patent Application Publication
(10) Pub. No.: US 2026/0244246 A1
(43) Pub. Date: Aug. 20, 2026

(54) ELECTRONIC DEVICE COMPRISING FLEXIBLE DISPLAY

(71) Applicant: Samsung Electronics Co., Ltd., Suwon-si (KR)

(72) Inventors: Youngkyong JO, Suwon-si (KR); Seokki KIM, Suwon-si (KR); Taehyeong RYU, Suwon-si (KR); Jinhyun PARK, Suwon-si (KR); Gyuhyun BYUN, Suwon-si (KR); Jungwon BYUN, Suwon-si (KR); Suyoel RYU, Suwon-si (KR); Bora LEE, Suwon-si (KR); Wonho LEE, Suwon-si (KR)

(21) Appl. No.: 19/648,450

(22) Filed: Apr. 15, 2026

Related U.S. Application Data
(63) Continuation of application No. PCT/KR2024/014787, filed on Sep. 27, 2024.

(30) Foreign Application Priority Data
Oct. 17, 2023 (KR) 10-2023-0139030
Nov. 10, 2023 (KR) 10-2023-0155701

(51) Int. Cl. G06F 1/16

(52) U.S. Cl. CPC G06F 1/1656; G06F 1/1641; G06F 1/1652

(57) ABSTRACT

The disclosure relates to an adhesive layer having different rigidities corresponding to a transformable area and a non-transformable area of a flexible display included in an electronic device. A flexible display is provided. The flexible display includes a display panel including a pixel array in which a plurality of subpixels outputting light of the same wavelength are disposed at a predetermined period, and a front cover disposed on one surface of the display panel, wherein the front cover includes a glass member having a first pattern formed by a plurality of openings or recesses formed corresponding to a variable region and disposed at a predetermined period, and wherein the first pattern forms an angle of 7 degrees to 38 degrees with respect to the pixel array.

### CROSS-REFERENCE TO RELATED APPLICATION(S)

This application is a continuation application, claiming priority under 35 U.S.C. § 365(c), of an International application No. PCT/KR2024/014787, filed on September 27, 2024, which is based on and claims the benefit of a Korean patent application number 10-2023-0139030, filed on October 17, 2023, in the Korean Intellectual Property Receiving Office, and of a Korean patent application number 10-2023-0155701, filed on November 10, 2023, in the Korean Intellectual Property Receiving Office, the disclosure of each of which is incorporated by reference herein in its entirety.

### BACKGROUND

### 1. Field

The disclosure relates to a flexible display and an electronic device including the same.

### 2. Description of Related Art

An electronic device requires a small profile for portability and requires a large-area display for providing users with substantial information. In order to achieve both a small profile and a large-area display in an electronic device, various form factors such as foldable, slidable, or rollable are emerging, departing from a rectangular bar-shaped form factor. An electronic device having such a form factor requires a flexible display capable of shape deformation by folding or bending.

To provide flexible performance of a flexible display, the flexible display may include a thin glass (e.g., ultra-thin glass) having different thicknesses in a folding region (or a sliding region or a bending region) and other regions. To increase flexible performance of the flexible display, the thin glass may be provided with a plurality of openings or recesses corresponding to the folding region. The plurality of openings or recesses may form a predetermined pattern. An adhesive member formed of a material having a low modulus may be provided along the predetermined pattern.

As an arrangement direction of pixels arranged in a lattice structure in a display panel included in the flexible display overlaps with an arrangement direction of the predetermined pattern, a moire phenomenon may occur in which light emitted from the pixels and light refracted at boundary regions of the pattern interfere with each other to produce a visible uniform pattern.

Further, due to a difference between a refractive index of the adhesive member provided in the predetermined pattern and a refractive index of the thin glass, a variable region and a non-variable region may be visually distinguishable in case that the flexible display is turned off, which may degrade user experience.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device including a flexible display for reducing visual quality degradation due to a lattice structure located in a folding region of a screen.

Additional aspects will be set forth in part in the description which follows and, in part, will be apparent from the description, or may be learned by practice of the presented embodiments.

In accordance with an aspect of the disclosure, a flexible display is provided. The flexible display includes a display panel including a pixel array in which a plurality of subpixels outputting light of the same wavelength are disposed at a predetermined period and a front cover disposed on one surface of the display panel, wherein the front cover includes a glass member having a first pattern formed by a plurality of openings or recesses formed corresponding to a variable region and disposed at a predetermined period, and wherein the first pattern forms an angle of 7 degrees to 38 degrees with respect to the pixel array.

In accordance with another aspect of the disclosure, an electronic device is provided. The electronic device includes a foldable housing providing a front surface of the electronic device and a rear surface of the electronic device, and a flexible display located in an inner space of the foldable housing, coupled with a front cover providing the front surface among the foldable housing, and visible through the front cover, wherein the flexible display includes a display panel including a pixel array in which a plurality of subpixels outputting light of the same wavelength are disposed at a predetermined period, wherein the front cover includes a glass member having a first pattern formed by a plurality of openings or recesses formed corresponding to a variable region and disposed at a predetermined period, and wherein the first pattern forms an angle of 7 degrees to 38 degrees with respect to the pixel array.

An electronic device according to an embodiment of the disclosure provides a flexible display with enhanced durability by providing a flexible pattern on a glass layer included in the flexible display.

An electronic device according to an embodiment of the disclosure provides a display with enhanced visibility by reducing a moire phenomenon.

A display included in an electronic device according to an embodiment of the disclosure provides a pattern having a preset shape corresponding to an off screen.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which

FIG. 1 is a view illustrating an unfolded state of an electronic device according to an embodiment of the disclosure;

FIG. 2 is a view illustrating a folded state of an electronic device according to an embodiment of the disclosure;

FIG. 3A is a cross-sectional view illustrating a display assembly taken along line C-C' of FIG. 1 according to an embodiment of the disclosure;

FIG. 3B is a cross-sectional view illustrating a display assembly taken along line C-C' of FIG. 1 according to an embodiment of the disclosure;

FIG. 3C is a cross-sectional view illustrating a display assembly taken along line C-C' of FIG. 1 according to an embodiment of the disclosure;

FIG. 4 is a cross-sectional view illustrating a flexible display included in a display assembly according to an embodiment of the disclosure;

FIG. 5 is a view illustrating a positional relationship between a pattern structure included in a front cover and a plurality of subpixels included in a flexible display in an unfolded state of an electronic device according to an embodiment of the disclosure;

FIG. 6 is an enlarged view illustrating a portion of FIG. 5 according to an embodiment of the disclosure;

FIG. 7A is an enlarged view illustrating a portion of FIG. 6 according to an embodiment of the disclosure;

FIG. 7B is an enlarged view illustrating a portion of FIG. 6 according to an embodiment of the disclosure;

FIG. 8A is a view illustrating a portion of a second pattern included in a front cover according to an embodiment of the disclosure;

FIG. 8B is a view illustrating a portion of a second pattern included in a front cover according to an embodiment of the disclosure;

FIG. 8C is a view illustrating a portion of a second pattern included in a front cover according to an embodiment of the disclosure;

FIG. 8D is a view illustrating a portion of a second pattern included in a front cover according to an embodiment of the disclosure;

FIG. 9A is a view illustrating a portion of a first layer including a first pattern according to an embodiment of the disclosure;

FIG. 9B is a view illustrating a portion of a first layer including a first pattern according to an embodiment of the disclosure;

FIG. 9C is a view illustrating a portion of a first layer including a first pattern according to an embodiment of the disclosure; and

FIG. 9D is a view illustrating a portion of a first layer including a first pattern according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

Further, an electronic device to be described may include a flexible display that is at least one of a foldable display, a rollable display, a slidable display, or a stretchable display. The flexible display may deform due to folding or bending. The operation in which the flexible display is folded or bent may be referred to as "deformation of the display," and this may mean deformation at a specific point according to characteristics of the flexible display. A region where the display is deformed may be referred to as a "variable region." Hereinafter, for convenience of description, an electronic device including a foldable display is mainly described, but the same may be applied to an electronic device including a flexible display deformed in various manners.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth^{®} chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

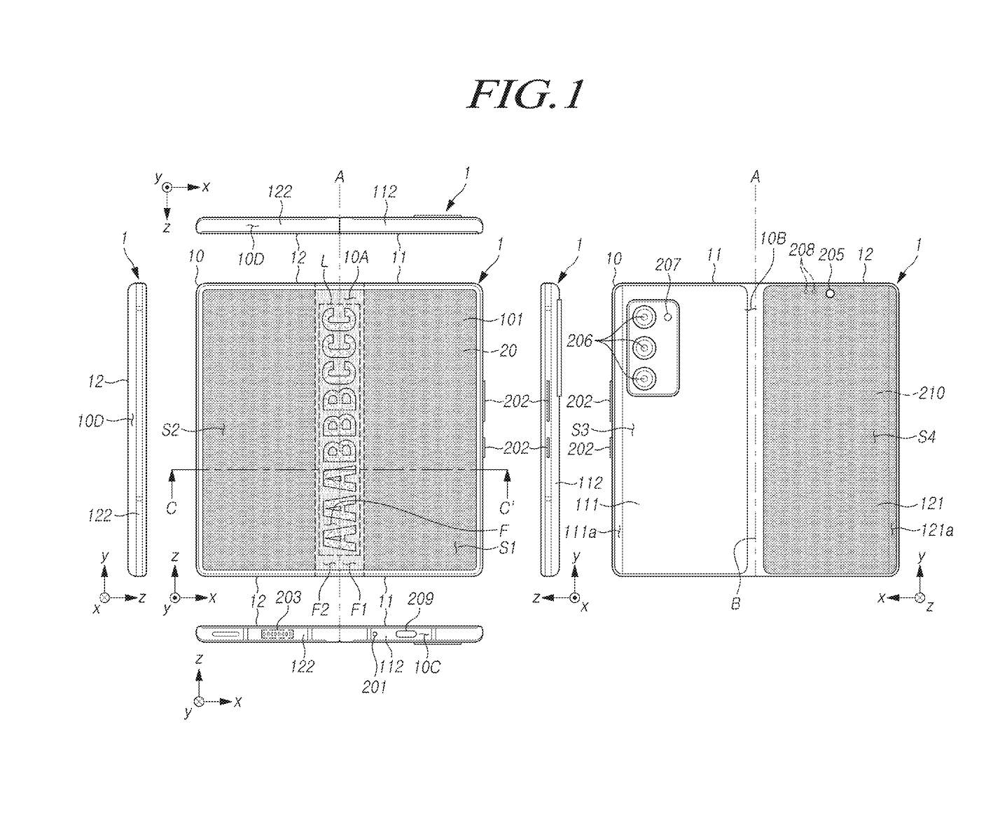

FIG. 1 is a view illustrating a flat state (or an unfolded state) of an electronic device according to an embodiment of the disclosure. The unfolded state of the electronic device 1 may be referred to as a "first state."

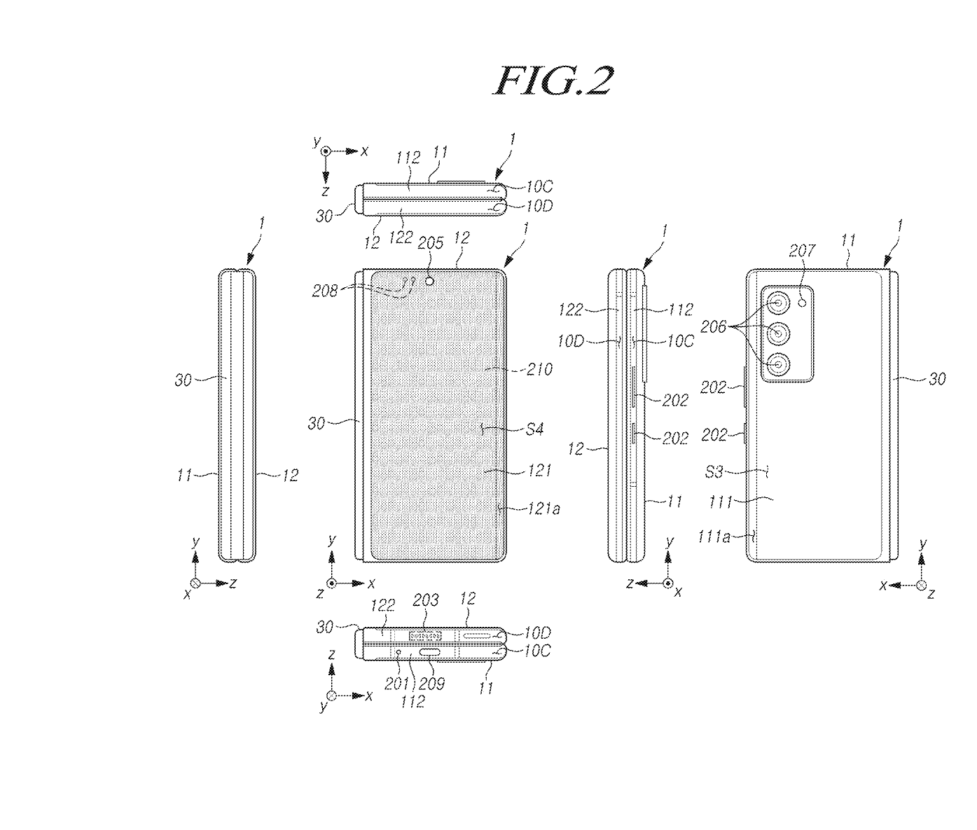

FIG. 2 is a view illustrating a folded state of an electronic device according to an embodiment of the disclosure. The folded state of the electronic device 1 may be referred to as a "second state." The electronic device 1 may have an intermediate state (or a third state) between the first state and the second state.

Referring to FIGS. 1 and 2, an electronic device (or a foldable electronic device) 1 may include a foldable housing 10 and a flexible display (or a flexible display module, a bendable display, or a bendable display module) 20. The foldable housing 10 may include a front surface 10A of the electronic device 1 and a rear surface 10B of the electronic device 1 located on an opposite side from the front surface 10A. For example, the front surface 10A of the electronic device 1 may be understood as a surface on which the flexible display 20 is exposed to the outside, and the rear surface 10B of the electronic device 1 may be understood as a surface located on an opposite side from the front surface 10A.

According to an embodiment, the foldable housing 10 may include a first side surface 10C and a second side surface 10D of the electronic device 1 at least partially surrounding a space between the front surface 10A and the rear surface 10B. The front surface 10A may include a first cover region S1, a second cover region S2, and a folding cover region F between the first cover region S1 and the second cover region S2. The folding cover region F may be referred to as a "variable region." In an unfolded state of the foldable housing 10 (or the electronic device 1), the front surface 10A may be substantially planar, and the first cover region S1, the second cover region S2, and the folding cover region F may face substantially the same direction. The rear surface 10B may include a third cover region S3 and a fourth cover region S4. The third cover region S3 may be located on an opposite side from the first cover region S1 of the front surface 10A and may be positioned to face an opposite direction from the first cover region S1. The fourth cover region S4 may be located on an opposite side from the second cover region S2 of the front surface 10A and may be positioned to face an opposite direction from the second cover region S2. In an embodiment, the foldable housing 10 may be implemented with an in-folding structure in which the front surface 10A is folded inward.

As an example, in an unfolded state of the foldable housing 10 (see FIG. 1), the folding cover region F may be disposed in a planar shape, and the first cover region S1 and the second cover region S2 may form an angle of about 180 degrees. In a folded state of the foldable housing 10, the folding cover region F may be disposed in a curved shape, and the first cover region S1 and the second cover region S2 may form an angle different from about 180 degrees. The folded state may include a fully folded state. The fully folded state may be a folded state in which the first cover region S1 and the second cover region S2 of the front surface 10A are disposed such that they do not become closer to each other any further.

As an example, in the folded state, the first cover region S1 and the second cover region S2 may form an angle of about 0° to about 10°. In the fully folded state, the front surface 10A may not be substantially exposed to the outside. The intermediate state may be understood as a state between the unfolded state and the fully folded state (or a state between the unfolded state and the fully folded state). The folding cover region F of the front surface 10A may be bent more in the fully folded state than in the intermediate state. The electronic device 1 may also be implemented with an out-folding structure in which the front surface 10A (or the screen) is folded outward.

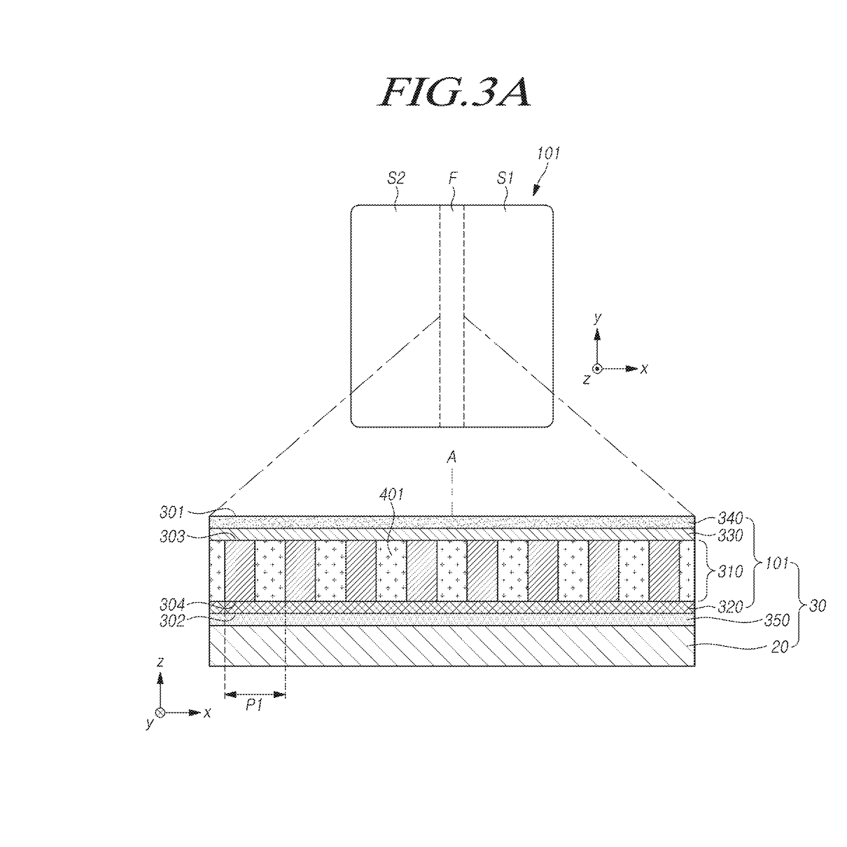

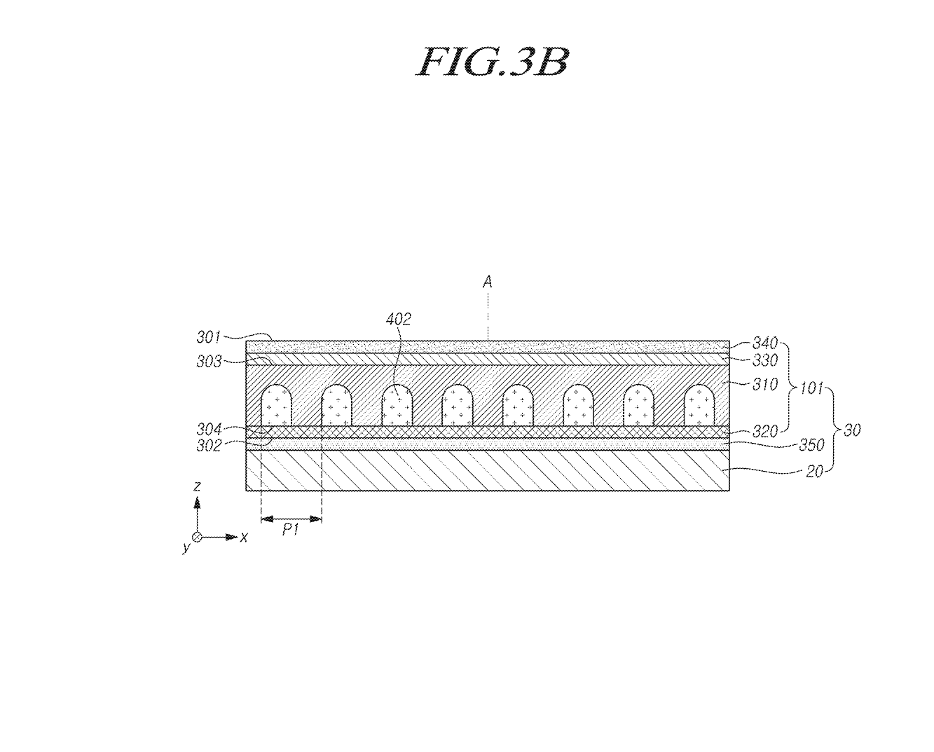

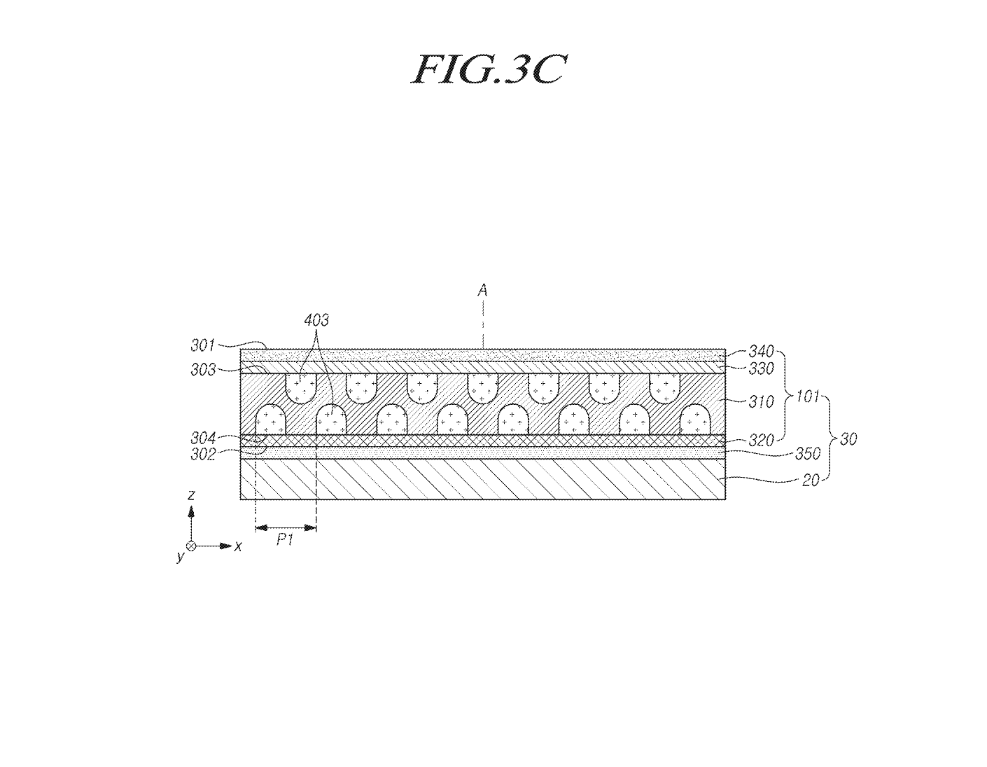

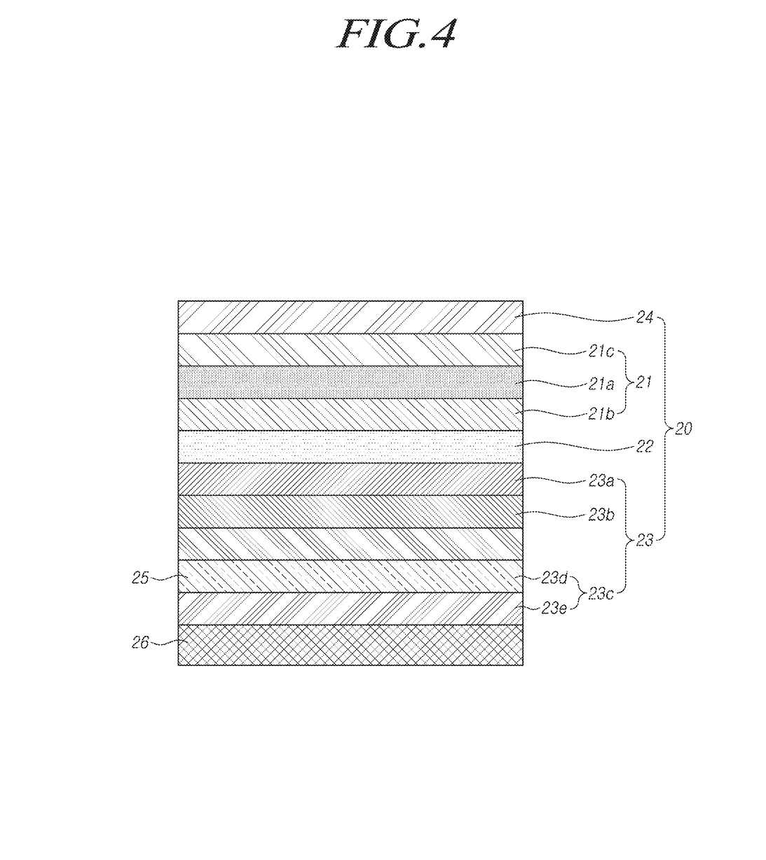

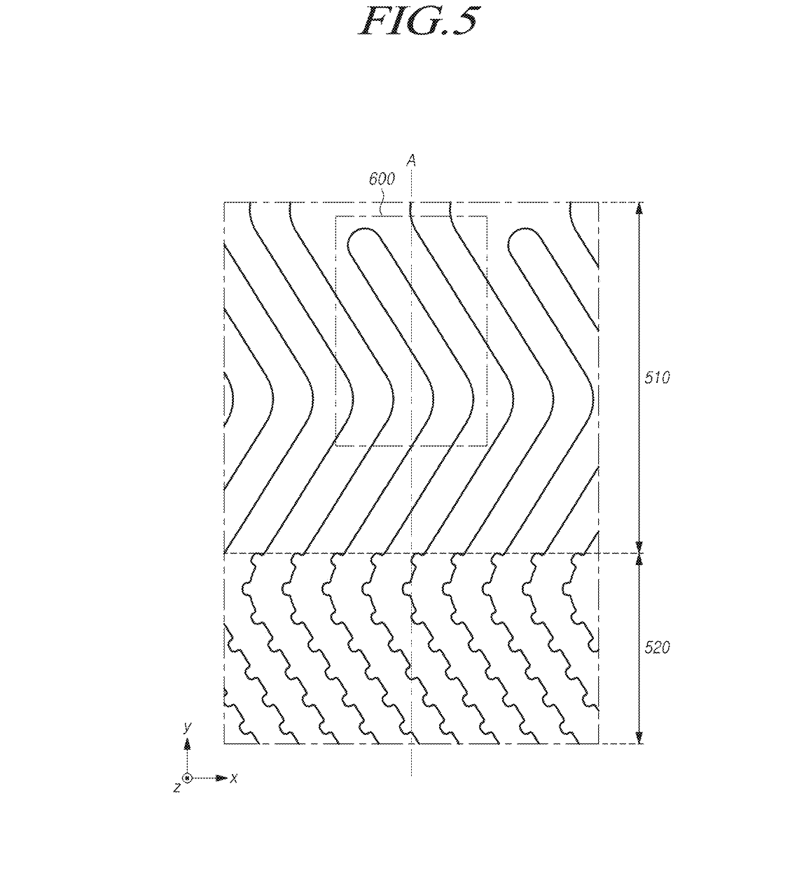

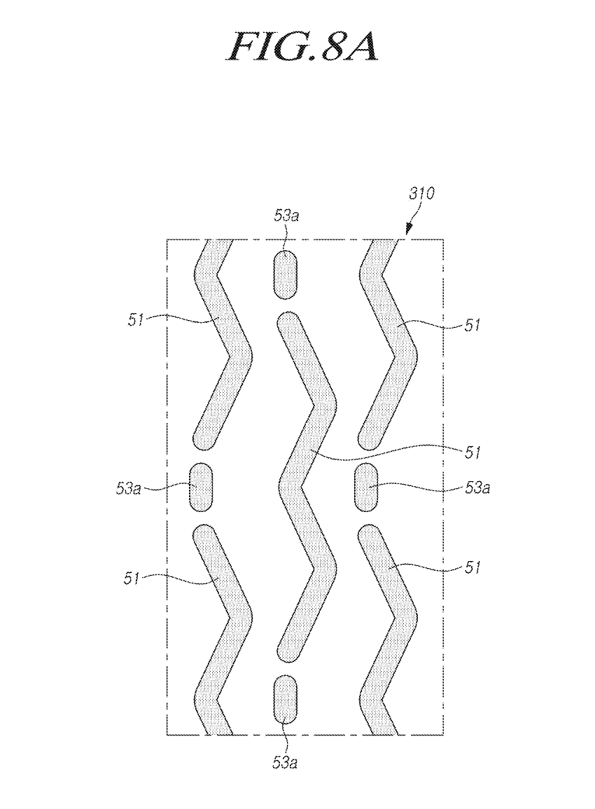

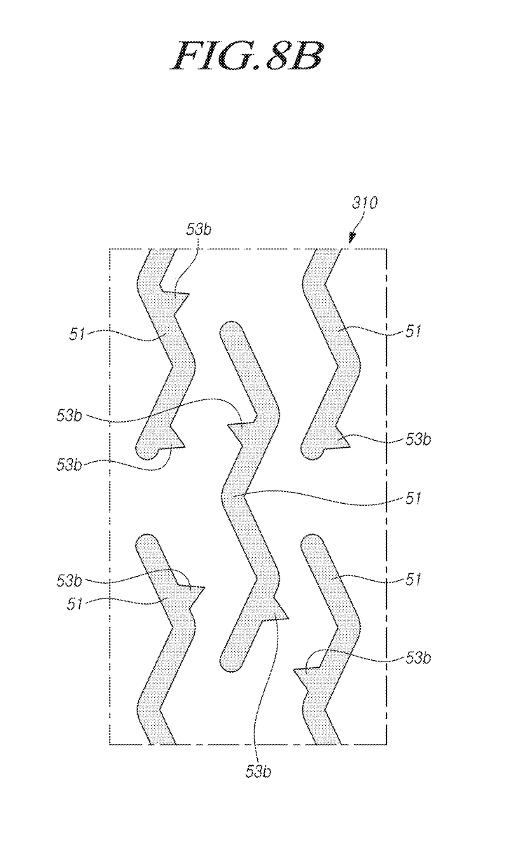

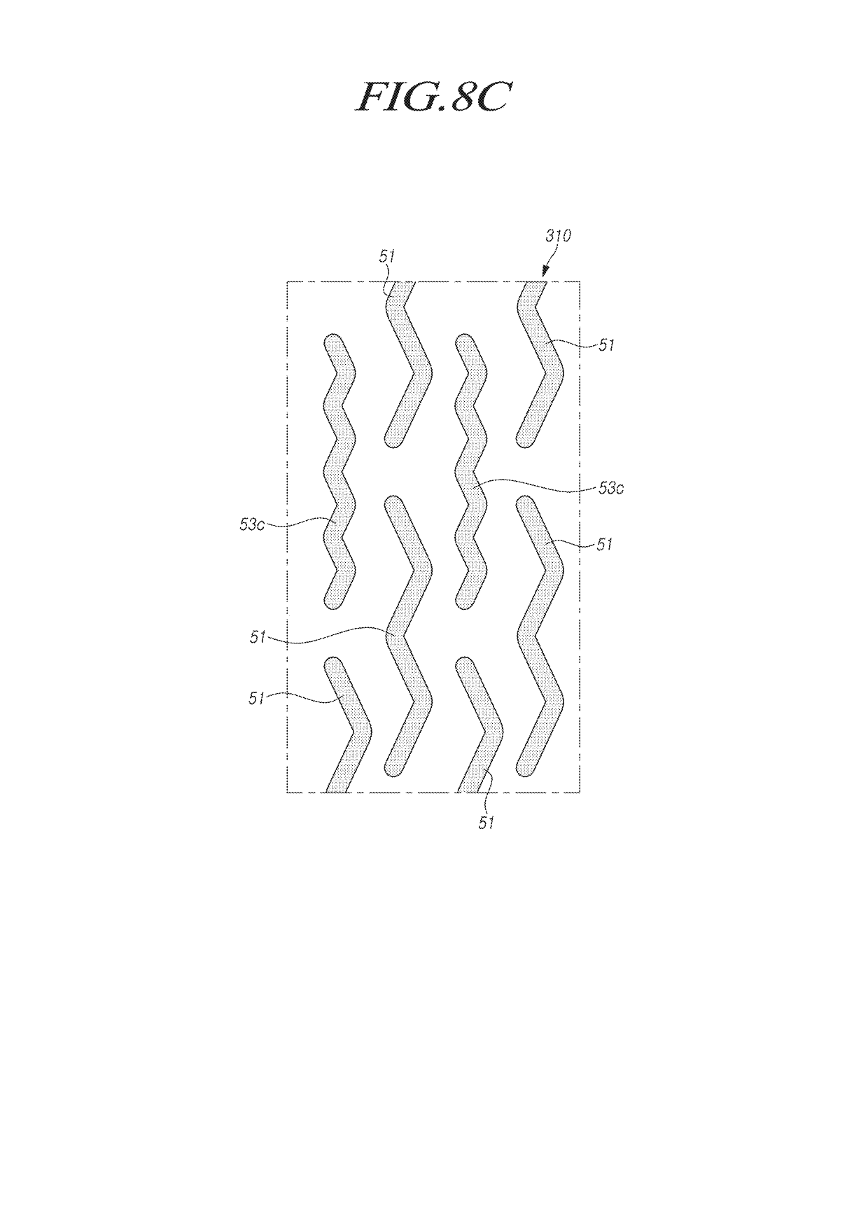

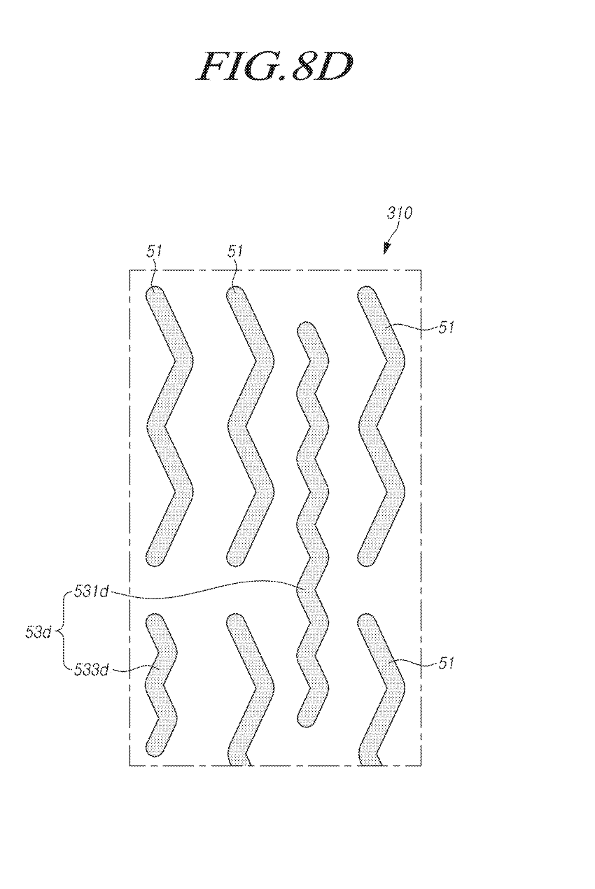

According to an embodiment, in case that the flexible display 20 is turned off, a visual shape L may be provided on at least a portion of the folding cover region F. The visual shape L may be provided by a first pattern (e.g., the first pattern 40 of FIG. 5) formed by a plurality of openings (e.g., the plurality of openings 401 of FIG. 3A) or a plurality of recesses (e.g., the plurality of recesses 402, 403 of FIG. 3B or 3C) provided in a first layer (e.g., the first layer 310 of FIG. 3A). To minimize a moire phenomenon, the first pattern 40 may be disposed at a predetermined angle with respect to a direction in which subpixels included in a display panel (e.g., the display panel 21 of FIG. 4) are disposed. As an example, in case that the flexible display 20 is turned off, the folding cover region F according to the first pattern 40 may be visible. The first pattern 40 may include a second pattern (e.g., the second pattern 50 of FIG. 5) visually distinguishable from the first pattern 40. The second pattern 50 may provide a visual shape L on at least a portion of the folding cover region F by being disposed to be visually distinguishable from the first pattern 40. For example, in response to the flexible display 20 being turned off, the second pattern 50 may display a character "AAABBBCCC" on the folding cover region F, but is not limited thereto, and may display visual shapes of various formats. The second pattern 50 may provide various types of visual shapes L on the folding cover region F. The visual shape L may include a character, a number, or a logo. The visual shape L may be a combination of at least two or more of the character, number, or logo. The second pattern 50 may have a predetermined shape or may be disposed in a predetermined manner to be distinguished from the first pattern 40. This is described with reference to FIGS. 8A to 8D.

According to an embodiment, the foldable housing 10 may include a front cover (e.g., a window) 101 at least partially providing (or forming) the front surface 10A. The flexible display 20 may be located in an inner space of the electronic device 1 at least partially overlapping the front cover 101. The front cover 101 may protect the flexible display 20 from the outside and may be substantially transparent. Light output from the flexible display 20 may pass through the front cover 101 and proceed to the outside. The flexible display 20 may include, e.g., a first display region (or a first active region) overlapping the first cover region S1 of the front surface 10A, a second display region (or a second active region) overlapping the second cover region S2 of the front surface 10A, and a third display region (or a third active region) overlapping the folding cover region F. As an example, the third display region may be referred to by other various terms such as a "folding display region," a "foldable display region," or a "bendable display region." A screen may indicate (or may be defined or interpreted as) a region capable of displaying an image in a device including the flexible display 20 and the front cover 101, and may include, e.g., a display region of the flexible display 20 and a region of the front cover 101 overlapping therewith. As an example, the front cover 101 may be provided (or formed) integrally with the flexible display 20 as a component included in the flexible display 20. In case that the front cover 101 is defined or interpreted as a component included in the flexible display 20, the front cover 101 may be excluded from the foldable housing 10. The front cover 101 may be implemented in a thin film shape such as a film to have flexibility. The front cover 101 may include, e.g., a plastic film (e.g., a polyimide film) or a thin glass (e.g., ultra-thin glass (UTG)). As an example, the front cover 101 may include a plurality of layers. For example, the front cover 101 may be in the form (not separately illustrated) in which a coating layer or a protective layer of various polymer materials (e.g., polyester (PET), polyimide (PI), or thermoplastic polyurethane (TPU)) is disposed on a plastic film or a thin glass.

According to an embodiment, the foldable housing 10 may include a first housing (or a first housing portion or a first housing structure) 11, a second housing (or a second housing portion or a second housing structure) 12, and a folding portion (or a foldable portion, a folding region, a bendable portion, or a bendable region) between the first housing 11 and the second housing 12. Coordinate axes illustrated for ease of understanding are based on the first housing 11, and for example, the first cover region S1 may face substantially in a +z-axis direction, and the third cover region S3 may face substantially in a -z-axis direction. The first housing 11 and the second housing 12 are connected by the folding portion and may be mutually rotatable about a folding axis A of the foldable housing 10. The folding portion may include, e.g., a hinge assembly (or a hinge structure). The folding axis A may be a rotation axis of the hinge assembly. In the illustrated example, the folding axis A may be parallel to the y-axis direction. The first housing 11 may include a first cover portion of the front cover 101 located on one side with respect to the folding axis A, a first rear cover 111 at least partially providing (or forming) the third cover region S3 of the rear surface 10B, and a first side member (or a first side bezel structure) 112 at least partially surrounding a space between the first cover portion and the first rear cover 111 and providing (or forming) the first side surface 10C. The first cover portion of the front cover 101 may provide (or form), e.g., the first cover region S1 and a first folding cover region F1 located on one side with respect to the folding axis A among the folding cover region F. The second housing 12 may include a second cover portion of the front cover 101 located on one side with respect to the folding axis A, a second rear cover 121 at least partially providing (or forming) the fourth cover region S4 of the rear surface 10B, and a second side member (or a side bezel structure) 122 at least partially surrounding a space between the second cover portion and the second rear cover 121 and providing (or forming) the second side surface 10D. The second cover portion of the front cover 101 may provide (or form), e.g., the second cover region S2 and a second folding cover region F2 located on another side with respect to the folding axis A among the folding cover region F. In the fully folded state of the foldable housing 10, the first side member 112 and the second side member 122 may at least partially overlap and be aligned. The first side member 112 and/or the second side member 122 may be provided (or formed) by, e.g., ceramic, a polymer, a metal (e.g., aluminum, stainless steel, or magnesium), or a combination of at least two of the materials. The first side member 112 and/or the second side member 122 may include various metal materials such as titanium, an amorphous alloy, a metal-ceramic composite material (e.g., cermet), stainless steel, magnesium, a magnesium alloy, aluminum, an aluminum alloy, a zinc alloy, or a copper alloy. The first rear cover 111 and/or the second rear cover 121 may be substantially opaque. The first rear cover 111 and/or the second rear cover 121 may be provided (or formed) by, e.g., coated or tinted glass, ceramic, a polymer, a metal (e.g., aluminum, stainless steel, or magnesium), or a combination of at least two of the materials. The first rear cover 111 or the second rear cover 121 may include a plate of various materials such as transparent glass, ceramic, or a polymer and at least one coating layer (not separately illustrated) disposed on the plate using coating. As another example, the first rear cover 111 or the second rear cover 121 may include a plate of various materials such as transparent glass, ceramic, or a polymer and a film having various visual effects (e.g., a decoration film) attached to the plate. As an example, the first rear cover 111 and the first side member 112 may be provided (or formed) integrally and may include the same material. As an example, the second rear cover 121 and the second side member 122 may be provided (or formed) integrally and may include the same material.

According to an embodiment, the folding portion may include a hinge housing 30. The hinge housing 30 may cover at least one hinge connecting the first housing 11 and the second housing 12. As an example, the hinge housing 30 may be referred to as a "hinge cover." In case that the electronic device 1 is transitioned from the unfolded state of FIG. 1 to the folded state of FIG. 2, the hinge housing 30 may cover the inside of the electronic device 1 such that it is not exposed as a gap B between the first housing 11 and the second housing 12 opens. As illustrated in FIG. 1, in the unfolded state of the electronic device 1, the gap B may be substantially absent, and the hinge housing 30 may be covered by the first housing 11 and the second housing 12 and may not be exposed to the outside. Although not illustrated, in the intermediate state of the electronic device 1, the hinge housing 30 may be partially exposed between the first housing 11 and the second housing 12. The hinge housing 30 may be more exposed in the folded state of FIG. 2 than in the intermediate state.

According to an embodiment, the foldable housing 10 may refer to a structure (e.g., a foldable housing structure or a foldable housing assembly) providing (or forming) at least a portion of the front surface 10A, the rear surface 10B, the first side surface 10C, and the second side surface 10D. For example, the foldable housing 10 may include a first housing portion, a second housing portion, and a folding portion connected to the first housing portion and the second housing portion. The folding portion may indicate (or may be defined or interpreted as) a portion more flexible than the first housing portion and the second housing portion, and may be bent in the folded state of the electronic device 1. The folding portion may include, e.g., a hinge assembly. For example, the folding portion may include a structure in which a plurality of bars are disposed (e.g., a multi-bar structure), and may be implemented with other various structures capable of having bending characteristics while connecting the first housing portion and the second housing portion without being limited thereto.

According to an embodiment, the electronic device 1 may include another display (hereinafter, a sub display) 210 located inside the first housing 11 adjacent to the first rear cover 111. A portion of the first rear cover 111 may overlap the sub display 210 and may be substantially transparent. The electronic device 1 may output an image using the sub display 210 instead of the flexible display 20 in the folded state of FIG. 2.

According to an embodiment, the second rear cover 121 may include a second curved region 121a seamlessly extending by being bent from the fourth cover region S4 toward the second cover region S2. The second curved region 121a may be provided (or formed) adjacent to a long edge of the second rear cover 121 substantially parallel to the folding axis A. The sub display 210 may include a flexible display that may be disposed in the corresponding shape.

According to an embodiment, the first rear cover 111 may include a first curved region 111a seamlessly extending by being bent from the third cover region S3 toward the first cover region S1. The first curved region 111a may be provided (or formed) adjacent to a long edge of the first rear cover 111 substantially parallel to the folding axis A. For example, in the unfolded state (see FIG. 1) or the folded state of the electronic device 1, for aesthetic purposes, the first curved region 111a and the second curved region 121a may be substantially symmetrically located on opposite sides. As an example, the first curved region 111a or the second curved region 121a may be omitted.

According to an embodiment, the electronic device 1 may include an input module, a sound output module, a camera module, a sensor module, or a connecting terminal. As an example, the electronic device 1 may omit at least one of the components or may additionally include other components. The location or number of components included in the electronic device 1 may vary and is not limited to the illustrated example.

As an example, the input module may include, e.g., a microphone located inside the electronic device 1 and a microphone hole 201 provided (or formed) on the first side surface 10C corresponding to the microphone. The location or number of the input module including the microphone and the corresponding microphone hole 201 may vary and is not limited to the illustrated example. As an example, the electronic device 1 may include a plurality of microphones capable of detecting a direction of sound.

As an example, the input module may include key input devices 202. The key input devices 202 may be located, e.g., in an opening (not illustrated) provided (or formed) on the first side surface 10C. As an example, the electronic device 1 may not include some or all of the key input devices 202, and a key input device not included may be implemented as a soft key using the flexible display 20 or the sub display 210. As an example, the input module may include at least one sensor module.

As an example, the sound output module may include, e.g., a speaker located inside the electronic device 1 and a speaker hole 203 provided (or formed) on the second side surface 10D corresponding to the speaker. The location or number of the sound output module including the speaker and the corresponding speaker hole 203 may vary and is not limited to the illustrated example. As an example, the microphone hole 201 and the speaker hole 203 may be implemented as a single hole. As an example, a piezo speaker with the speaker hole 203 omitted may be implemented. The sound output module may include, e.g., a call receiver located inside the electronic device 1 and a receiver hole (not illustrated) provided (or formed) on the fourth cover region S4 corresponding to the call receiver.

As an example, the camera module may include, e.g., a first camera module (or a front camera module) 205 located corresponding to the fourth cover region S4, or a plurality of second camera modules (or rear camera modules) 206 located corresponding to the third cover region S3. The first camera module 205 and/or the plurality of second camera modules 206 may include one or more lenses, an image sensor, and/or an image signal processor. The location or number of the first camera module 205 or the plurality of second camera modules 206 may vary and is not limited to the illustrated example.

According to an embodiment, the sub display 210 may include an opening aligned with the first camera module 205. External light may pass through the second rear cover 121 and the opening of the sub display 210 to reach the first camera module 205. As an example, the opening of the sub display 210 may be provided (or formed) in a notch shape according to the location of the first camera module 205. As an example, the first camera module 205 may be located on a rear surface of the sub display 210 or below or beneath the sub display 210, and may perform a related function (e.g., image capturing) without the location of the first camera module 205 being visually distinguished (or exposed). For example, the first camera module 205 may include a hidden under display camera (e.g., an under display camera (UDC)). For example, the first camera module 205 may be aligned and located in a recess provided (or formed) on a rear surface of the sub display 210. The first camera module 205 may be disposed to overlap at least a portion of a screen and may acquire an image of an external subject without being visually exposed to the outside. In this case, a portion of the sub display 210 at least partially overlapping the first camera module 205 may include a different pixel structure and/or line structure compared to other regions. For example, a portion of the sub display 210 at least partially overlapping the first camera module 205 may have a different pixel density (e.g., a number of pixels per unit area) compared to other regions. A pixel structure and/or line structure provided (or formed) in a portion of the sub display 210 at least partially overlapping the first camera module 205 may reduce loss of light between the outside and the first camera module 205. As an example, no pixel may be disposed in a portion of the sub display 210 at least partially overlapping the first camera module 205.

According to an embodiment, the plurality of second camera modules 206 may have different properties (e.g., angle of view) or functions from each other, and may include, e.g., a dual camera or a triple camera. The plurality of second camera modules 206 may include a plurality of camera modules including lenses having different angles of view, and the electronic device 1 may be configured to change an angle of view illustrating the camera module performed in the electronic device 1 based on a user's selection. The plurality of second camera modules 206 may include at least one of a wide-angle camera, a telephoto camera, a color camera, a monochrome camera, or an infrared (IR) camera (e.g., a time of flight (TOF) camera, a structured light camera). As an example, the IR camera may also be operated as at least a portion of the sensor module. The electronic device 1 may include a flash 207 as a light source for the plurality of second camera modules 206. The flash 207 may include, e.g., a light emitting diode or a xenon lamp.

According to an embodiment, the sensor module may generate an electrical signal or a data value corresponding to an operation state inside the electronic device 1 or an environmental state outside. The sensor module may include, e.g., at least one of a proximity sensor, a gesture sensor, a gyro sensor, a barometric sensor, a magnetic sensor, an acceleration sensor, a grip sensor, a color sensor, an IR sensor, a biometric sensor (e.g., a fingerprint sensor, a heart rate monitor (HRM) sensor), a temperature sensor, a humidity sensor, or an illuminance sensor.

According to an embodiment, the sensor module may include an optical sensor 208 located inside the electronic device 1 corresponding to the fourth cover region S4. The optical sensor 208 may include, e.g., a proximity sensor or an illuminance sensor. The optical sensor 208 may be aligned with an opening provided (or formed) in the sub display 210. External light may pass through the second rear cover 121 and the opening of the sub display 210 to reach the optical sensor 208. As an example, the optical sensor 208 may be located on a rear surface of the sub display 210 or below or beneath the sub display 210, and may perform a related function without the location of the optical sensor 208 being visually distinguished (or exposed). As an example, the optical sensor 208 may be aligned and located in a recess provided (or formed) on a rear surface of the sub display 210. The optical sensor 208 may be disposed to overlap at least a portion of a screen and may perform a sensing function without being exposed to the outside. In this case, a portion of the sub display 210 at least partially overlapping the optical sensor 208 may include a different pixel structure and/or line structure (not separately illustrated) compared to other regions. For example, a portion of the sub display 210 at least partially overlapping the optical sensor 208 may have a different pixel density compared to other regions (not separately illustrated). As an example, the sensor module may include a fingerprint sensor located below the sub display 210. The fingerprint sensor may be implemented in a capacitive method, an optical method, or an ultrasonic method. A pixel structure and/or line structure provided (or formed) in a portion of the sub display 210 at least partially overlapping the sensor module may reduce loss in case that various types of signals (e.g., light or ultrasonic waves) related to the sensor module pass through between the outside and the sensor module. As an example, a plurality of pixels may not be disposed in a portion of the sub display 210 at least partially overlapping the sensor module.

According to an embodiment, the connecting terminal may include a connector (e.g., a USB connector) located inside the electronic device 1. The electronic device 1 may include a connector hole 209 provided (or formed) on the first side surface 10C corresponding to the connector. The electronic device 1 may transmit and/or receive power and/or data with an external electronic device electrically connected to the connector through the connector hole 209. The location or number of the connector and the corresponding connector hole 209 may vary and is not limited to the illustrated example.

According to an embodiment, the electronic device 1 may include a detachable pen input device (e.g., an electronic pen, a digital pen, or a stylus pen). For example, the pen input device may be attached to and detached from the hinge housing 30. The hinge housing 30 may include a recess, and the pen input device may be fitted into the recess. The pen input device may be attached to and detached from, e.g., a recess of the hinge housing 30 exposed to the outside in the folded state or the intermediate state of the electronic device 1. As an example, the electronic device 1 may be implemented such that the pen input device may be inserted into an inner space of the first housing 11 or the second housing 12.

FIGS. 3A, 3B and 3C are cross-sectional views illustrating a display assembly taken along line C-C' of FIG. 1 according to various embodiments of the disclosure. In other words, the display assembly 30 included in the electronic device 1 may be understood as a cross-section cut parallel to the x-z plane.

FIG. 3A may be understood as illustrating a case in which a plurality of openings 401 penetrating between a third surface 303 and a fourth surface 304 of a first layer 310 is provided. FIG. 3B may be understood as illustrating a case in which a plurality of recesses 402 recessed by a predetermined thickness from the fourth surface 304 of a first layer 310 is provided. FIG. 3C may be understood as illustrating a case in which a plurality of recesses 403 recessed by a predetermined thickness from the third surface 303 and the fourth surface 304 of a first layer 310 is provided. Hereinafter, FIGS. 3A to 3C may correspond except for the plurality of openings 401 or the plurality of recesses 402, 403 provided in the first layer 310, and thus after describing the structure of FIG. 3A as a center, FIGS. 3B and 3C is described focusing on differences.

Referring to FIG. 3A, a display assembly 30 may include a front cover 101, a flexible display 20, and/or an optically clear adhesive member 350 between the front cover 101 and the flexible display 20. The front cover 101 and the flexible display 20 may be coupled using the optically clear adhesive member 350. The optically clear adhesive member 350 may include, e.g., an optically clear adhesive (OCA), an optically clear resin (OCR), or a super view resin (SVR). The front cover 101 and the optically clear adhesive member 350 may be substantially transparent, and light output from the flexible display 20 may pass through the optically clear adhesive member 350 and the front cover 101 and proceed to the outside. The flexible display 20 may include a first display region corresponding to the first cover region S1 of the front cover 101, a second display region corresponding to the second cover region S2 of the front cover 101, and a third display region (or a folding display region) corresponding to the folding cover region F of the front cover 101. The cross-sectional view illustrated in FIG. 3 may correspond to a portion of the display assembly 30 corresponding to the folding cover region F of the front cover 101.

According to an embodiment, the front cover 101 may include a first surface 301 and a second surface 302 located on an opposite side from the first surface 301. The first surface 301 may provide (or form) the front surface 10A of the electronic device 1. The first surface 301 and the second surface 302 may be substantially parallel, and a thickness of the front cover 101 (e.g., a distance between the first surface 301 and the second surface 302) may be substantially the same in the first cover region S1, the second cover region S2, and the folding cover region F.

According to an embodiment, the front cover 101 may include a first layer 310, a second layer 320, a third layer 330, and/or a fourth layer 340. The first layer 310 and the second layer 320 may be located between the third layer 330 and the optically clear adhesive member 350. The third layer 330 may be located closer to the fourth layer 340 than the first layer 310 and between the fourth layer 340 and the optically clear adhesive member 350.

According to an embodiment, the first layer 310 may be, e.g., a transparent plate including glass or plastic (e.g., polyimide). In an embodiment, the first layer 310 may include a glass plate (e.g., a thin glass or an ultra-thin glass) formed (or made) of elements such as selenium and sulfur, oxides such as silicon, boron, and germanium, or inorganic materials such as oxide salts, sulfides, selenides, and halides. The glass may include, e.g., a basic network-forming material or may further include an auxiliary material chemically bonded thereto to have properties such as mechanical strength, chemical durability, transparency, or electrical insulation. For example, the first layer 310 may be formed through an operation of forming a thin glass and an operation of strengthening the thin glass. The thin glass may have a thickness of, e.g., about 30 μm (micrometer) to about 1000 μm, but the disclosure is not limited thereto. The operation of strengthening the thin glass may inject a special material to a predetermined depth or more into the thin glass. The first layer 310 may have a smooth feel inherent to glass or surface uniformity. The first layer 310 including glass may have a higher hardness compared to a plastic film (e.g., a polyimide film). In case that the first layer 310 including glass provides (or forms) the front surface 10A (see FIG. 1) of the electronic device 1 (e.g., in case that the third layer 330 and the fourth layer 340 are omitted), the first layer 310 may have excellent resistance to scratches compared to a plastic film (e.g., a polyimide film). The first layer 310 may include glass having various optical properties. For example, the first layer 310 may be implemented to pass or not pass light of a specific wavelength band such as ultraviolet light or infrared light.

According to an embodiment, the first layer 310 may include glass having a relatively low permittivity to prevent energy loss. For example, the first layer 310 may include glass having a relatively low dielectric loss. As a result, performance degradation of at least one component (e.g., an electromagnetic induction panel, a touch sensing circuit, or an antenna) forming an electric field or a magnetic field toward the first surface 301 may be decreased. As an example, since sodium ions or the like in glass may carry charges (e.g., ionic conduction) under an electric field action, the first layer 310 may include glass having a low alkali content such as sodium.

According to an embodiment, the first layer 310 may include a third surface 303 facing the first surface 301 of the front cover 101 and a fourth surface 304 facing the second surface 302 of the front cover 101. The third surface 303 and the fourth surface 304 may be substantially parallel. The first layer 310 may be provided (or formed) with a thickness (e.g., a separation distance between the third surface 303 and the fourth surface 304) that contributes to the bending stress not substantially reaching the yield stress in the folded state of the electronic device 1 (see FIG. 2). As an example, a portion of the first layer 310 corresponding to the folding cover region F of the front cover 101 may be implemented to have a relatively thinner thickness compared to the first cover region S1 and/or the second cover region S2 of the front cover 101.

According to an embodiment, the thickness of the first layer 310 may be limited to a value that may reduce a radius of curvature or curvature as much as possible without breakage during bending (or while reducing bending stress). As an example, the thickness of the first layer 310 may be limited to, e.g., 1.5 times to 3.5 times the radius of curvature.

According to an embodiment, the first layer 310 may include a first pattern (or a first pattern structure) 40 provided (or formed) corresponding to the folding cover region F of the front cover 101. The first pattern 40 of the first layer 310 may include, e.g., a lattice structure having a plurality of openings (or slits) 401 penetrating between the third surface 303 and the fourth surface 304. The plurality of openings 401 included in the lattice structure may be periodically provided (or formed), and may have substantially the same shape and may be repeatedly disposed at regular intervals. In an embodiment, the plurality of openings 401 may be in a series of corrugated form. In an embodiment, the plurality of openings 401 may be provided (or formed) in the form including a series of sinuous curves, bends, loops, turns, or windings. The shape of the plurality of openings 401 included in the lattice structure may otherwise be various.

As an example, the lattice structure including the plurality of openings 401 may be referred to by other terms such as a "through pattern," an "opening pattern," a "hole pattern," or a "lattice pattern." The first pattern 40 of the first layer 310 may contribute to flexibility of the folding cover region F and the corresponding portion of the display assembly 30.

Referring to FIGS. 3B and 3C, the first pattern 40 of the first layer 310 may be modified to a recess pattern including a plurality of recesses 402, 403. The recess pattern may be referred to by other terms such as, e.g., a "non-through pattern," a "depression pattern," or an "intaglio pattern." The plurality of recesses 402, 403 may refer to (or may be defined or interpreted as) a portion provided (or formed) to be indented on the fourth surface 304. A first portion of the first layer 310 including the plurality of recesses 402, 403 may have a first thickness with respect to the third surface 303, and a second portion of the first layer 310 not including the plurality of recesses may have a second thickness thicker than the first thickness with respect to the third surface 303. The first thickness and the second thickness may have a length of, e.g., 50 um to 500 um. However, the disclosure is not limited thereto.

As an example, the first pattern 40 provided (or formed) as a lattice structure including the plurality of openings 401 or a recess pattern including the plurality of recesses 402, 403 may extend to the first cover region S1 or the second cover region S2 of the front cover 101.

As an example, the plurality of openings 401 or the plurality of recesses 402, 403 included in the first pattern 40 of the first layer 310 may be formed using various methods such as laser, computer numerical control (CNC) machining, scratching, blasting, polishing, or etching (e.g., chemical etching).

According to an embodiment, due to the plurality of openings 401 or the plurality of recesses 402, 403 included in the first pattern 40 of the first layer 310, a moire phenomenon may occur. The moire phenomenon may occur due to a difference between the first period P1 of the first pattern 40 and an arrangement period P2 between subpixels. Here, a form in which a red pixel R, a green pixel G, and a blue pixel B among the plurality of subpixels are respectively disposed may be referred to as a "pixel array."

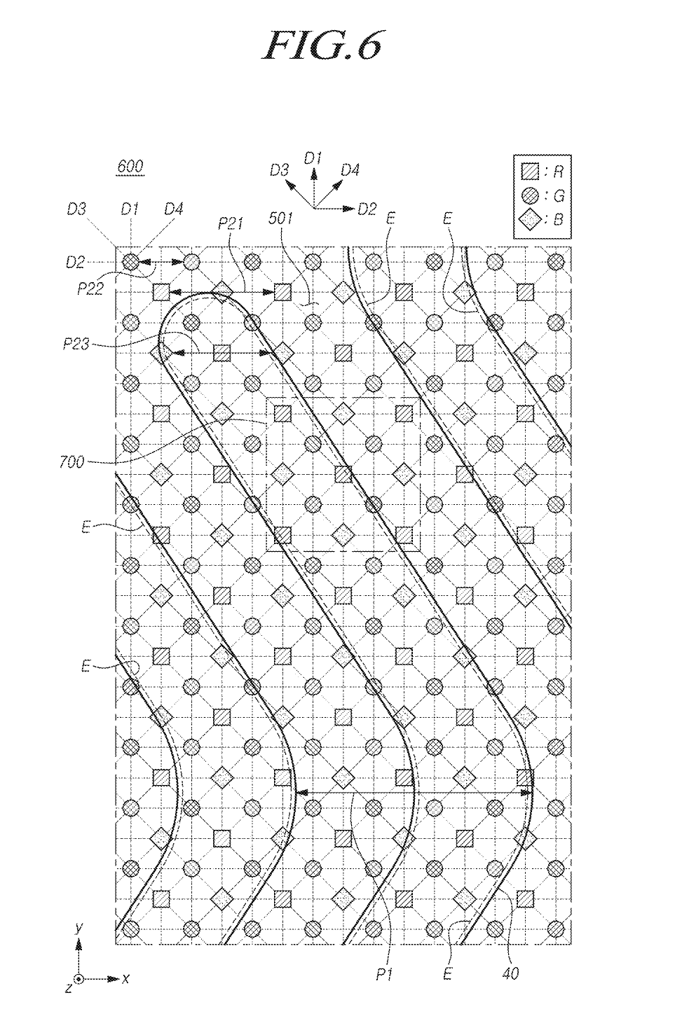

According to an embodiment, the moire phenomenon may vary in degree to which the moire phenomenon is visible according to an angle that the first pattern 40 forms with the pixel array. To minimize the moire phenomenon, the first pattern 40 may form a predetermined angle with respect to an arrangement of the plurality of subpixels included in a display panel (e.g., the display panel 21 of FIG. 4). The pixel array may be disposed in a first arrangement direction, a second arrangement direction, a third arrangement direction, and a fourth arrangement direction (e.g., the first arrangement direction to the fourth arrangement direction D1, D2, D3, D4 of FIG. 6), and the first pattern 40 may form a predetermined angle with respect to the first arrangement direction to the fourth arrangement direction D1, D2, D3, D4 in which the pixel array is disposed.

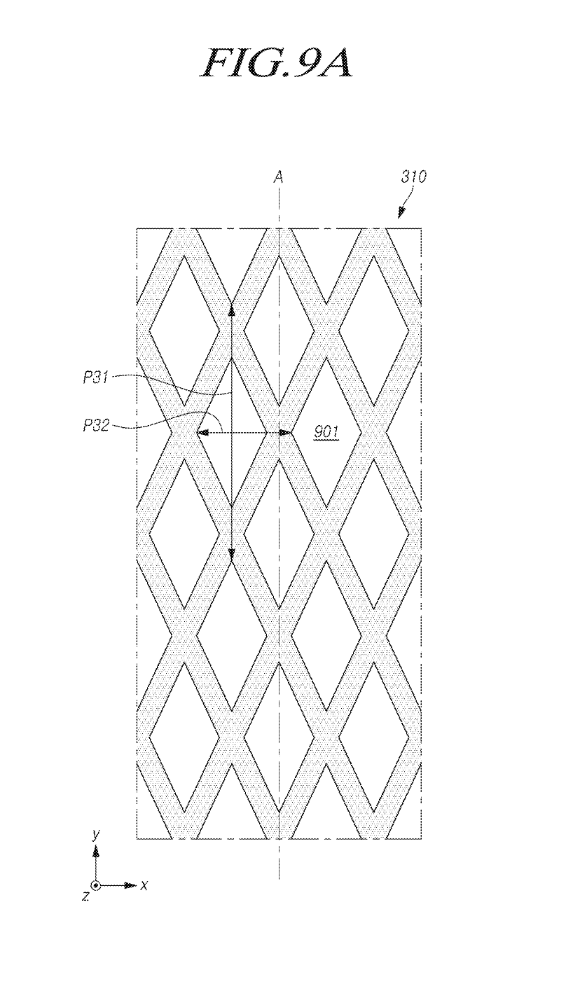

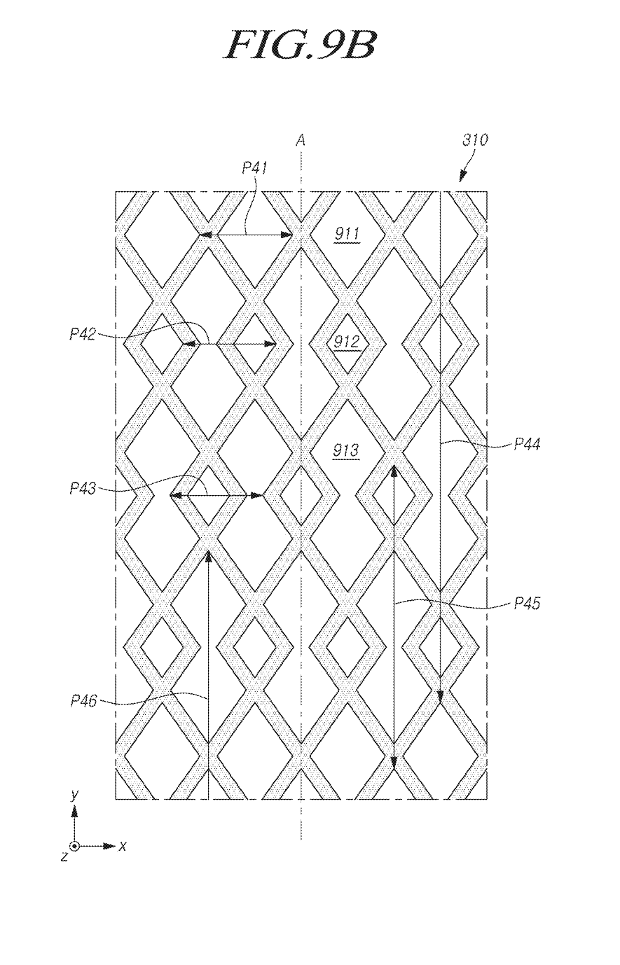

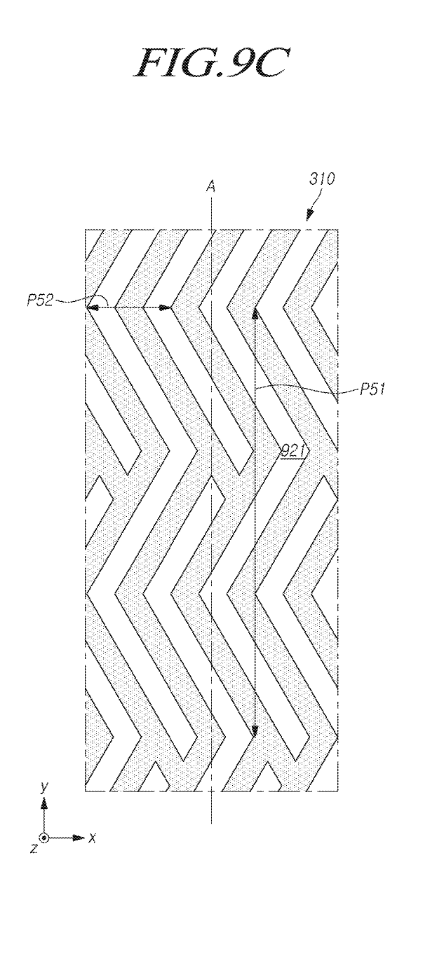

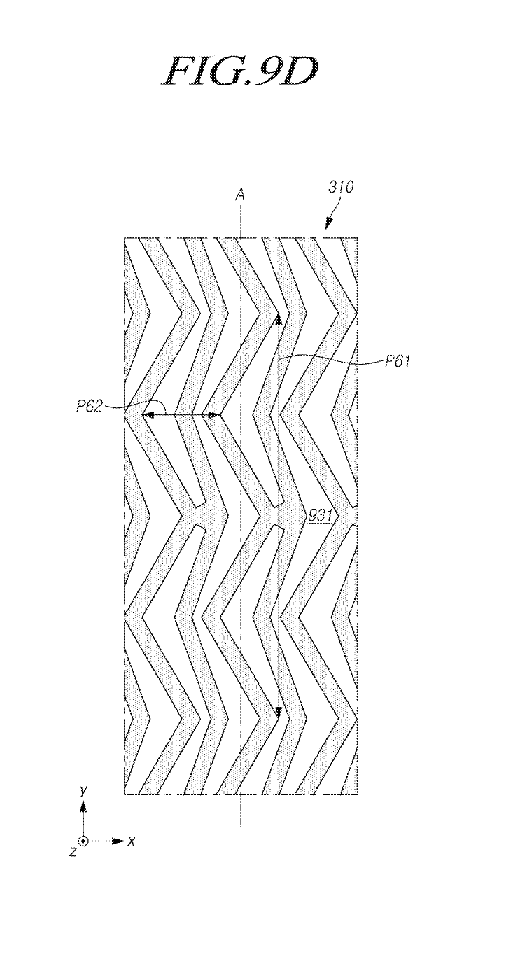

According to an embodiment, the predetermined angle may be determined such that the moire phenomenon is minimized. As an example, the moire phenomenon may be minimized in case that an angle that the first pattern 40 forms with the pixel array is 7° to 38°. For this purpose, the first pattern 40 may form various patterns while maintaining an angle of 7° to 38° with the pixel array. The shapes of the various patterns are described with reference to FIGS. 9A to 9D.

According to an embodiment, due to the first pattern 40 formed in the folding cover region F, in case that the flexible display 20 is turned off, the folding cover region F in which the first pattern 40 is present and the first cover region S1 and the second cover region S2 in which the first pattern 40 is not present may be visually distinguished from the electronic device 1 in an unfolded state. As an example, in case that external light is reflected by the first pattern 40 formed in the folding cover region F, a pattern provided in the folding cover region F may be visible due to the light reflected corresponding to the first pattern 40, which may degrade user experience. For this purpose, the first pattern 40 may include a second pattern (e.g., the second pattern 50 of FIG. 5) visually distinguishable from the first pattern 40 in case that the flexible display 20 is turned off. The second pattern 50 may provide a visual shape L on at least a portion of the folding cover region F by being visually distinguishable from the second pattern 50. The visual shape L may include, e.g., a visual design such as a character or number symbol, or a logo. As an example, in FIG. 1, in response to the flexible display 20 being turned off, the second pattern 50 may display a character "AAABBBCCC" on the folding cover region F. However, without being limited thereto, the second pattern 50 may provide various types of visual shapes L on the folding cover region F.

According to an embodiment, the second pattern 50 may be disposed at the same period as a period P1 where the first pattern 40 is disposed or may be disposed at a different period to be visually distinguished from the first pattern 40. The second pattern 50 may also be disposed aperiodically.

According to an embodiment, the second pattern 50 may have a regular shape or may have an irregular shape. The second pattern 50 may be disposed by combining a pattern having a regular shape and a pattern having an irregular shape.

According to an embodiment, the second pattern 50 may include a main pattern and a sub pattern in contact with at least a portion of the main pattern.

According to an embodiment, the second pattern 50 may extend from at least a portion of the first pattern 40. The shape or arrangement of the second pattern 50 is described with reference to FIGS. 8A to 8D.

According to an embodiment, the second layer 320 may be coupled with the first layer 310. The second layer 320 may include a substantially transparent polymer. A smooth second surface 302 of the front cover 101 for bonding with the flexible display 20 may be provided (or formed) by the second layer 320, and the plurality of openings 401 or the plurality of recesses 402, 403 of the first layer 310 may be provided (or formed) by the second layer 320 or the third layer 330, and the second layer 320 may include a portion disposed (or filled) in the plurality of openings 401 or the plurality of recesses 402, 403 of the first layer 310. As an example, the third layer 330 may be disposed on one surface provided (or formed) by a portion of the first layer 310 and the second layer 320 located in the plurality of openings 401.

According to an embodiment, an adhesive member having a relatively low modulus value may be provided to be filled in the plurality of openings 401 or the plurality of recesses 402, 403 of the first layer 310. The adhesive member may be composed of a material having a predetermined refractive index and a predetermined modulus value. The predetermined refractive index may have a value of, e.g., 1.48 to 1.55. The predetermined modulus value may have a modulus value of, e.g., 0.01 MPa to 1 GPa.

According to an embodiment, the second layer 320 may reinforce the first layer 310. Impact resistance or durability of the first layer 310 may be reinforced by the second layer 320. The second layer 320 may mitigate bending stress occurring in a bending region (or a bendable region) bent corresponding to the folding cover region F of the front cover 101 among the first layer 310 in the folded state of the electronic device 1. Since bending stress occurring in the first layer 310 due to repeated transitions between the unfolded state and the folded state of the electronic device 1 may cause breakage due to fatigue accumulation leading to degradation or loss of elasticity, the second layer 320 may mitigate the bending stress occurring in the first layer 310.

According to an embodiment, the second layer 320 may have a form and/or physical property (e.g., hardness or ductility) such that flexibility of the folding cover region F of the front cover 101 does not decrease below a designated level. A designated level of flexibility may be a value that allows the display assembly 30, 60 to smoothly deform during state transitions (e.g., transitions between the unfolded state and the folded state) of the electronic device 1 while substantially preventing breakage or permanent deformation thereof. For example, in case that the electronic device 1 is transitioned from the folded state to the unfolded state, the second layer 320 may have elasticity that contributes to the front cover 101 being restored substantially without plastic deformation. The second layer 320 may have, e.g., an elongation of about 4% to about 20%.

According to an embodiment, since the folding cover region F of the front cover 101 includes the plurality of openings 401 (or the plurality of recesses 402, 403 of FIGS. 3B and 3C) compared to the first cover region S1 and the second cover region S2, the folding cover region F may be relatively vulnerable to external impact or external pressure. For example, in case that a user input is made by contacting a pen tip of a pen input device on the first surface of the front cover 101, the folding cover region F of the front cover 101 may be at risk of being damaged by external impact or external pressure applied from the pen tip compared to the first cover region S1 and the second cover region S2. According to an embodiment, the second layer 320 may reduce breakage of the first layer 310 from external impact or external pressure applied to the first layer 310. The second layer 320 may mitigate stress that may occur in the first layer 310 due to external impact or external pressure. The second layer 320 may have a hardness that may reduce breakage of the folding cover region F of the front cover 101 corresponding to external impact or external pressure. The hardness of the second layer 320 may provide resistance to local plastic deformation of the folding cover region F due to external impact or external pressure and may reduce breakage of the folding cover region F.

According to an embodiment, the second layer 320 may include an organic material of an acrylic type, a urethane type, or a silicone type.

According to an embodiment, the second layer 320 may be formed using an ultraviolet (UV) molding liquid (e.g., a photocurable material). The first layer 310 may be disposed on a mold (e.g., a UV molding mold) into which UV molding liquid is injected and pressed with a roller, and as a result, the UV molding liquid may be evenly spread between the first layer 310 and the mold. In an embodiment, the first layer 310 may be coated with a primer using a method such as vacuum deposition or spattering and then disposed on a mold into which UV molding liquid is injected and pressed. In this case, a bonding layer (not illustrated) including a primer may be between the first layer 310 and the second layer 320. The bonding layer including a primer may allow the first layer 310 and the second layer 320 to be bonded without gaps and may enhance bonding strength thereof. In case that ultraviolet light (or light of a designated frequency) is radiated toward the first layer 310, the UV molding liquid may react to ultraviolet light transmitted through the first layer 310 and cure, and as a result, a sheet in which the second layer 320 is attached to the first layer 310 may be formed.

According to an embodiment, the third layer 330 may reinforce the display assembly 30 or 60 or the first layer 310. The third layer 330 may include a substantially transparent polymer. As an example, the third layer 330 may be disposed on one surface provided (or formed) by a portion of the first layer 310 and the second layer 320 located in the plurality of openings 401 (or the plurality of recesses 402, 403) using an optically clear adhesive member (not illustrated) such as OCA, OCR, or SVR. As an example, the optically clear adhesive member may be provided with a material having a predetermined modulus value. The optically clear adhesive member may have a modulus value of, e.g., 0.01 MPa to 1 GPa.

According to an embodiment, the third layer 330 may be disposed on the first layer 310 using an optically clear adhesive member (not illustrated). The third layer 330 may have a form (e.g., thickness) and/or physical property (e.g., hardness or ductility) such that flexibility of the folding cover region F of the front cover 101 does not decrease below a designated level. In case that the electronic device 1 is transitioned from the folded state to the unfolded state, the third layer 330 may have elasticity that contributes to the front cover 101 being restored substantially without plastic deformation.

According to an embodiment, the fourth layer 340 may be disposed on the third layer 330 to provide (or form) the first surface 301 of the front cover 101. The fourth layer 340 may be disposed on the third layer 330 using an optically clear adhesive member (not illustrated) such as OCA, OCR, or SVR. The fourth layer 340 may be, e.g., a final layer for neatly protecting the front cover 101 from the outside as a transparent coating layer. The transparent coating layer may include a clear layer and may include, e.g., a UV clear layer formed (or made) of a UV curing material. The fourth layer 340 may have resistance to external impact (or scratches). The fourth layer 340 may have a form (e.g., thickness) and/or physical property (e.g., hardness or ductility) such that flexibility of the folding cover region F of the front cover 101 does not decrease below a designated level. In case that the electronic device 1 is transitioned from the folded state to the unfolded state, the fourth layer 340 may have elasticity that contributes to the front cover 101 being restored substantially without plastic deformation. As an example, the third layer 330 may include an optically clear adhesive member. Although not illustrated, a layer of various functions disposed on the fourth layer 340 and providing (or forming) the front surface 10A of the electronic device 1 may be further added. Further, although not illustrated, in case that the first layer 310 is implemented to substantially provide (or form) the front surface 10A of the electronic device 1, the third layer 330 and the fourth layer 340 may be omitted.

According to an embodiment, two layers bonded to each other among a plurality of layers included in the front cover 101 (e.g., the first layer 310, the second layer 320, the third layer 330, the fourth layer 340, or an optically clear member between any two layers) may be implemented to include a material that may reduce a difference in refractive index therebetween. For example, in case that a difference in refractive index between two layers is decreased, a reflectance of an interface between the two layers may be decreased, and reflection at the interface and resulting loss of light may be decreased, and thus a clearer image may be visible through a screen. The difference in refractive index between two layers may be, e.g., about 0.01 or less corresponding to a level illustrating a clear image.

According to an embodiment, two layers bonded to each other among a plurality of layers included in the front cover 101 (e.g., the first layer 310, the second layer 320, the third layer 330, the fourth layer 340, or an optically clear member between any two layers) may be bonded substantially without an air gap. For example, since an air gap may cause loss of light from the flexible display 20, leading to image quality degradation, the second layer 320, the third layer 330, or the fourth layer 340 may be formed by applying a liquid material and curing it, and as a result, air gap occurrence may be decreased. Further, the optically clear adhesive member 350 may include a material that may reduce a difference in refractive index with the front cover 101 and a difference in refractive index with the flexible display 20.

FIG. 4 is a cross-sectional view illustrating a flexible display included in a display assembly according to an embodiment of the disclosure. The flexible display 20 may be implemented by stacking a plurality of layers.

Referring to FIG. 4, the flexible display 20 may include a display panel 21, a base film 22, a lower panel 23, and/or an optical layer 24. The display panel 21 may be located between the optical layer 24 and the base film 22. The base film 22 may be located between the display panel 21 and the lower panel 23. The optical layer 24 may be located between the optically clear adhesive member 350 and the display panel 21. An adhesive member (not illustrated) of various polymers may be disposed between the display panel 21 and the base film 22, between the base film 22 and the lower panel 23, and/or between the display panel 21 and the optical layer 24.

According to an embodiment, the display panel 21 may include a light emitting layer 21a, a thin film transistor (TFT) film 21b, and/or an encapsulation layer (e.g., a thin-film encapsulation (TFE)) 21c. The light emitting layer 21a may include a plurality of pixels implemented with a light emitting element such as an organic light emitting diode (OLED) or a micro LED. The light emitting layer 21a may be disposed on the TFT film 21b through organic material evaporation. The TFT film 21b may be located between the light emitting layer 21a and the base film 22. The TFT film 21b may be a film structure (or a film) in which at least one TFT is disposed on a flexible substrate (e.g., a PI film) through a series of processes such as deposition, patterning, and etching. At least one TFT may control a current for a light emitting element of the light emitting layer 21a to adjust on or off of a pixel or brightness of a pixel. At least one TFT may be implemented as an amorphous silicon (a-Si) TFT, a liquid crystalline polymer (LCP) TFT, a low-temperature polycrystalline oxide (LTPO) TFT, or a low-temperature polycrystalline silicon (LTPS) TFT.

According to an embodiment, the display panel 21 may include a storage capacitor, and the storage capacitor may maintain a voltage signal on a pixel, maintain a voltage input to a pixel within one frame, or reduce gate voltage change of a TFT due to leakage current during a light emission time. According to a routine (e.g., initialization, data write) controlling at least one TFT, the storage capacitor may maintain a voltage applied to a pixel at regular time intervals.

According to an embodiment, the display panel 21 may be implemented based on OLED, and the encapsulation layer 21c may cover the light emitting layer 21a. Since an organic material emitting light and an electrode in an OLED may react very sensitively to oxygen and/or moisture and lose light emitting characteristics, the encapsulation layer 21c may seal the light emitting layer 21a so that oxygen and/or moisture do not penetrate into the OLED. The encapsulation layer 21c may serve as a pixel protective layer for protecting the plurality of pixels of the light emitting layer 21a.

According to an embodiment, the base film 22 may include a flexible film formed (or made) of a polymer or plastic such as polyimide or polyester. The base film 22 may serve to support and protect the display panel 21. As an example, the base film 22 may be referred to as a "protective film," a "back film," or a "back plate."

According to an embodiment, the lower panel 23 may include a plurality of layers for various functions. An adhesive member (not illustrated) of various polymers may be disposed between a plurality of layers included in the lower panel 23. The lower panel 23 may include, e.g., a light blocking layer 23a, a buffer layer 23b, or a lower layer 23c. The light blocking layer 23a may be located between the base film 22 and the buffer layer 23b. The buffer layer 23b may be located between the light blocking layer 23a and the lower layer 23c. The light blocking layer 23a may at least partially block light incident from the outside. For example, the light blocking layer 23a may include an embossed layer. The embossed layer may be a black layer including an uneven pattern. The buffer layer 23b may mitigate external impact applied to the flexible display 20. For example, the buffer layer 23b may include a sponge layer or a cushion layer. The lower layer 23c may diffuse, disperse, or dissipate heat generated in the electronic device 1 or the flexible display 20. The lower layer 23c may absorb or shield electromagnetic waves. The lower layer 23c may mitigate external impact applied to the electronic device 1 or the flexible display 20.

According to an embodiment, the lower layer 23c may include a composite sheet 23d or a conductive sheet 23e. In an embodiment, the composite sheet 23d may be a sheet processed by combining layers or sheets having different properties. For example, the composite sheet 23d may include at least one of polyimide or graphite. The composite sheet 23d may also be replaced with a single sheet including one material (e.g., polyimide, or graphite). The composite sheet 23d may be located between the buffer layer 23b and the conductive sheet 23e. The conductive sheet 23e may reduce or shield electromagnetic interference (EMI) to the flexible display 20. The conductive sheet 23e may include copper but, without limitations thereto, may include other various metal materials.

According to an embodiment, at least a portion of the lower layer 23c may be a conductive member (e.g., a metal plate), may help reinforce rigidity of the electronic device 1, may shield surrounding noise, and may be used to disperse heat emitted from surrounding heat dissipation components (e.g., a display driver circuit (e.g., DDI)). The conductive member may include, e.g., at least one of copper (Cu), aluminum (Al), stainless steel (SUS), or CLAD (e.g., a laminated member in which SUS and Al are alternately disposed). Further, the lower layer 23c may include various types of layers for various functions.

According to an embodiment, at least one additional polymer layer (e.g., a layer including PI, PET, or TPU) may be further disposed on a rear surface of the display panel 21 in addition to the base film 22.

According to an embodiment, at least one of the plurality of layers included in the lower panel 23 (e.g., the light blocking layer 23a, the buffer layer 23b, the composite sheet 23d, and the conductive sheet 23e) may be omitted. Further, an arrangement order of the plurality of layers included in the lower panel 23 is not limited to the illustrated example and may be varied.

According to an embodiment, the optical layer 24 may include a polarizing layer (or a polarizer) or a retardation layer (or a retarder). The polarizing layer and the retardation layer may enhance outdoor visibility of a screen. The optical layer 24 may, e.g., selectively pass light vibrating in a predetermined direction generated from a light source of the display panel 21. As an example, one layer combining the polarizing layer and the retardation layer may be provided, and such a layer may be defined or interpreted as a "circular polarizing layer." As an example, the polarizing layer (or the circular polarizing layer) may be omitted, and in this case, a black pixel define layer (PDL) and/or a color filter may be included to replace the polarizing layer.

According to an embodiment, the flexible display 20 may include a touch sensing circuit (e.g., a touch sensor). The touch sensing circuit may be implemented with a transparent conductive layer (or a film) based on various conductive materials such as indium tin oxide (ITO).

According to an embodiment, the touch sensing circuit may be disposed between the front cover 101 and the optical layer 24. In other words, the touch sensing circuit may be implemented as an add-on type.

According to an embodiment, the touch sensing circuit may be disposed between the optical layer 24 and the display panel 21. In other words, the touch sensing circuit may be implemented as an add-cell type.

According to an embodiment, the display panel 21 may include a touch sensing circuit or a touch sensing function. In other words, the display panel 21 may include an in-cell type touch sensing circuit or touch sensing function.

According to an embodiment, the flexible display 20 may include a conductive pattern such as a metal mesh (e.g., an aluminum metal mesh) as a touch sensing circuit disposed on the encapsulation layer 21c between the encapsulation layer 21c and the optical layer 24. For example, corresponding to bending of the flexible display 20, the metal mesh may have greater durability than a transparent conductive layer implemented with ITO.

According to an embodiment, the flexible display 20 may further include a pressure sensor capable of measuring an intensity (pressure) of a touch.

According to an embodiment, a plurality of layers, a stacked structure thereof, or a stacking order included in the display panel 21 or the lower panel 23 may vary. The flexible display 20 may be implemented by omitting some of the components or by adding other components according to a provision form or a convergence trend thereof.

According to an embodiment, an electromagnetic induction panel (e.g., a digitizer) 25 may be located between the buffer layer 23b and the lower layer 23c. The electromagnetic induction panel 25 may be located between the composite sheet 23d and the conductive sheet 23e of the lower layer 23c, or the electromagnetic induction panel 25 may be located between the light blocking layer 23a and the buffer layer 23b. The electromagnetic induction panel 25 may be implemented in the form such as a flexible film or a flexible sheet.

According to an embodiment, the electromagnetic induction panel 25 may be provided (or formed) as, e.g., a flexible printed circuit board.

According to an embodiment, in case of alternating current is supplied to the electromagnetic induction panel 25, an electromagnetic field may be formed by a plurality of electrode patterns included in the electromagnetic induction panel 25. A pen input device may be implemented with an electromagnetic induction method (e.g., an electromagnetic resonance (EMR) method). The pen input device may include a resonance circuit, and the resonance circuit may be linked with the electromagnetic induction panel 25. In case that a pen tip of the pen input device is brought close to the front surface 10A of the electronic device 1, a current may flow in a coil included in the resonance circuit of the pen input device by electromagnetic induction. The pen input device may generate a signal (e.g., a radio frequency signal) (e.g., a position signal, a pen pressure signal, and/or an angle signal) regarding user input on a screen using energy supplied from the electromagnetic induction panel 25 and transmit it to a screen (e.g., the electromagnetic induction panel 25).

According to an embodiment, the electromagnetic induction panel 25 may include a shielding sheet. The shielding sheet may be located on a rear surface of a flexible printed circuit board including a plurality of electrode patterns (e.g., a surface of the flexible printed circuit board facing the conductive sheet 23e in the illustrated embodiment). The shielding sheet may prevent interference between the components from an electromagnetic field generated from components included in the electronic device 1. The shielding sheet may block the electromagnetic field generated from the components to allow an input from the pen input device to be accurately transmitted to a coil included in the electromagnetic induction panel 25.

According to an embodiment, the electromagnetic induction panel 25 may be defined or interpreted as a component included in the flexible display 20. According to an embodiment, a pen input device may be implemented with an active electrical stylus (AES) method or an electric coupled resonance (ECR) method. In this case, the electromagnetic induction panel 25 may be omitted.

According to an embodiment, a support sheet 26 may be disposed on a rear surface of the flexible display 20. For example, the support sheet 26 may be disposed on a rear surface of the lower panel 23 included in the flexible display 20. The support sheet 26 may contribute to durability of the display assembly 30 or the flexible display 20. The support sheet 26 may, e.g., reduce an effect of a load or stress that may occur during transitions between the unfolded state (see FIG. 1) and the folded state (see FIG. 2) of the electronic device 1 on the flexible display 20.

According to an embodiment, the support sheet 26 may be formed (or made) of various metal materials and/or non-metal materials (e.g., a polymer). The support sheet 26 may include, e.g., stainless steel. As another example, the support sheet 26 may include an engineering plastic. As an example, the support sheet 26 may be implemented integrally with the flexible display 20.

According to an embodiment, the support sheet 26 may include a lattice structure (not separately illustrated) provided (or formed) in a portion corresponding to the folding cover region F of the front cover 101. The lattice structure may include, e.g., a plurality of openings (or slits). For example, the plurality of openings may be periodically provided (or formed) and may have substantially the same shape and may be repeatedly disposed at regular intervals. As an example, the lattice structure including the plurality of openings may be referred to as an "opening pattern." The lattice structure may contribute to flexibility of a portion of the display assembly 30 corresponding to the folding cover region F.

According to an embodiment, the support sheet 26 may include a recess pattern (not illustrated) including a plurality of recesses instead of the lattice structure.

According to an embodiment, the lattice structure or recess pattern contributing to flexibility of the flexible display 20 may be further extended to other portions.

According to an embodiment, the support sheet 26 including the lattice structure or the recess pattern or a conductive member corresponding thereto may be provided (or formed) as a plurality of layers.

According to an embodiment, the support sheet 26 may be omitted or may be defined or interpreted as a component included in the flexible display 20.

According to an embodiment, the first pattern 40 of the first layer 310 included in the front cover 101 may have the plurality of openings 401 (see FIG. 3) or the plurality of recesses 402, 403 disposed based on a first pitch (or a first interval) P1. The first pitch P1 may be understood as an interval where an opening or a recess of a substantially constant shape is periodically and repeatedly disposed. Referring to FIG. 3, an embodiment of the display assembly 30 in an unfolded state, the plurality of openings 401 may be disposed in a direction substantially perpendicular to the folding axis A (e.g., the x-axis direction) based on the first pitch P1. As an example, the plurality of recesses 402, 403 may be disposed in a direction substantially perpendicular to the folding axis A (e.g., the x-axis direction) based on the first pitch P1.

According to an embodiment, the first pattern 40 of the first layer 310 may vary and is not limited to the illustrated example. For example, the first pattern 40 may be modified to include a first sub pattern in which a first type of first opening or first recess is disposed in a first direction at a pitch of a first value, and a second sub pattern in which a second opening or second recess different from the first type is disposed in a second direction different from the first direction at a pitch of the first value or a second value different from the first value. As another example, the first pattern 40 may be modified to a form in which the same opening or recess is disposed in at least two or more directions (e.g., directions perpendicular to each other) at the same or different pitches. A shape of the first pattern 40 may be variously provided (or formed) to secure flexibility of the first layer 310.

According to an embodiment, the first pattern 40 of the first layer 310 may be provided (or formed) to reduce a moire phenomenon in case that light is output from the plurality of subpixels included in the display panel 21. The moire phenomenon may be, e.g., a phenomenon in which in case that light is output from the plurality of subpixels included in the display panel 21, the first pattern 40 of the first layer 310 causes light interference and a pattern of a predetermined pattern (e.g., a moire pattern) is visible. The plurality of subpixels may include, e.g., a plurality of first subpixels outputting light of a first color among primary colors, a plurality of second subpixels outputting light of a second color among primary colors, and a plurality of third subpixels outputting light of a third color among primary colors. The plurality of first subpixels may provide (or form), e.g., a first pixel pattern disposed at a 2-1th pitch (or a 21st interval) P21 in substantially the same direction as a direction in which the plurality of openings 401 or the plurality of recesses 402, 403 included in the first pattern 40 of the first layer 310 are disposed at the first pitch P1. The plurality of second subpixels may provide (or form), e.g., a second pixel pattern disposed at a 2-2th pitch (or a 22nd interval) P22 in substantially the same direction as a direction in which the plurality of openings 401 or the plurality of recesses 402, 403 included in the first pattern 40 of the first layer 310 are disposed at the first pitch P1. The plurality of third subpixels may provide (or form), e.g., a third pixel pattern disposed at a 2-3th pitch (or a 23rd interval) in substantially the same direction as a direction in which the plurality of openings 401 or the plurality of recesses 402, 403 included in the first pattern 40 of the first layer 310 are disposed at the first pitch P1.

FIG. 5 is a view illustrating a positional relationship between a pattern structure (e.g., the first pattern and the second pattern) included in the front cover and a plurality of subpixels included in a flexible display in an unfolded state of an electronic device according to an embodiment of the disclosure. FIG. 5 may be understood as an enlarged view illustrating a portion of the folding cover region F of FIG. 1.

FIG. 6 is an enlarged view illustrating a portion (e.g., a portion 600 of FIG. 5) including plurality of subpixels of FIG. 5 according to an embodiment of the disclosure. In other words, FIG. 6 may be understood as an enlarged view for illustrating the first pattern 40.

Referring to FIGS. 5 and 6, the plurality of subpixels 501 may include a plurality of red subpixels R outputting (or representing) light of a red color, a plurality of green subpixels G outputting (or representing) light of a green color, and a plurality of blue subpixels B outputting (or representing) light of a blue color. The plurality of subpixels 501 may be included in, e.g., the light emitting layer 21a of the display panel 21. In an embodiment, one pixel (or a unit pixel) may be implemented with three subpixels, e.g., a red subpixel R, a green subpixel G, and a blue subpixel B. As an example, an arrangement of the plurality of subpixels 501 may be implemented differently from the illustrated example. For example, one pixel may be implemented with two subpixels, e.g., a red subpixel R and a green subpixel G, and a blue subpixel B and a green subpixel G, and an arrangement of the plurality of subpixels 501 may be modified differently from the illustrated example. Light output from the red subpixel R, light output from the green subpixel G, and light output from the blue subpixel B may have different wavelengths.

According to an embodiment, the red subpixel R may provide (or form), e.g., a first pixel pattern disposed at a 2-1th pitch (or a 21st interval) P21 in substantially the same direction as a direction in which the plurality of openings 401 or the plurality of recesses 402, 403 (see FIG. 6) included in the first pattern 40 of the first layer 310 are disposed at the first pitch (or first interval) P1. The green subpixel G may provide (or form), e.g., a second pixel pattern disposed at a 2-2th pitch (or a 22nd interval) P22 in substantially the same direction as a direction in which the plurality of openings 401 or the plurality of recesses 402, 403 included in the first pattern 40 of the first layer 310 are disposed at the first pitch P1. The blue subpixel B may provide (or form), e.g., a third pixel pattern disposed at a 2-3th pitch (or a 23rd interval) P23 in substantially the same direction as a direction in which the plurality of openings 401 or the plurality of recesses 402, 403 included in the first pattern 40 of the first layer 310 are disposed at the first pitch P1. The 2-1th pitch P21, the 2-2th pitch P22, or the third pitch P23 may be about 30 μm to about 300 μm, but the disclosure is not limited thereto.

According to an embodiment, the 2-1th pitch P21 where the first pixel pattern is disposed, the 2-2th pitch P22 where the second pixel pattern is disposed, and the 2-3th pitch P23 where the third pixel pattern is disposed may be substantially the same. In this case, the 2-1th pitch P21, the 2-2th pitch P22, and the 2-3th pitch P23 may be collectively referred to as the second pitch P2. Hereinafter, for convenience of description, it is assumed that the 2-1th pitch to 2-3th pitch P21, P22, P23 are substantially the same, and this is referred to as the second pitch P2.

According to an embodiment, the plurality of openings 401 or the plurality of recesses 402, 403 included in the first pattern 40 of the first layer 310 may include an edge E. The edge E of the first pattern 40 may indicate an edge shape of the plurality of openings 401 or the plurality of recesses 402, 403 in a direction substantially parallel to the display panel 21 (e.g., the display panel 21 of FIG. 5) in which the plurality of subpixels 501 are included. The edge E of the first pattern 40 may correspond to, e.g., a surface (e.g., an inner surface) included in the plurality of openings 401 substantially perpendicular to the third surface 303 or the fourth surface 304 of FIG. 4. The first layer 310 may be provided (or formed) as a thin film having a thickness of, e.g., about 30 μm to about 1000 μm, and a surface included in the plurality of openings 401 may be interpreted as having a negligible height compared to a width of the plurality of openings 401. In an embodiment, other various terms replacing the term "edge" may be used.

According to an embodiment, an arrangement direction regarding the red subpixel R, the green subpixel G, or the blue subpixel B in the plurality of subpixels 501 may be defined. An arrangement direction regarding the plurality of subpixels 501 may be defined based on, e.g., a combination of two subpixels outputting light of the same wavelength (or the same color) and located adjacent to each other at a separation distance that may substantially affect each other (e.g., light interference). For example, arrangement directions regarding a plurality of red subpixels outputting light of a red color having a first wavelength, green subpixels outputting light of a green color having a second wavelength, and blue subpixels outputting light of a blue color having a third wavelength may include, as illustrated, a first arrangement direction D1, a second arrangement direction D2, a third arrangement direction D3, and/or a fourth arrangement direction D4.

According to an embodiment, the folding cover region F may include a first region 510 and a second region 520. The first region 510 may be understood as a region in which the plurality of openings 401 or the plurality of recesses 402, 403 formed in a first layer (e.g., the first layer 310 of FIGS. 3A to 3C) of the flexible display 20 form the first pattern 40. At least a portion of the second region 520 may be understood as a region in which the plurality of openings 401 or the plurality of recesses 402, 403 formed in the first layer 310 of the flexible display 20 form the second pattern 50.

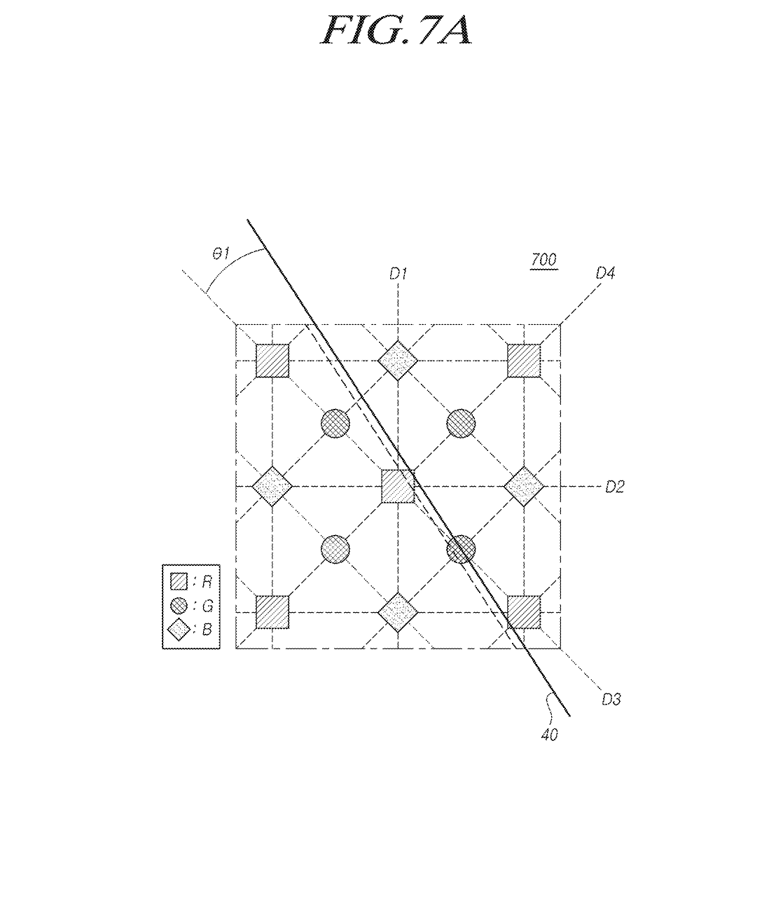

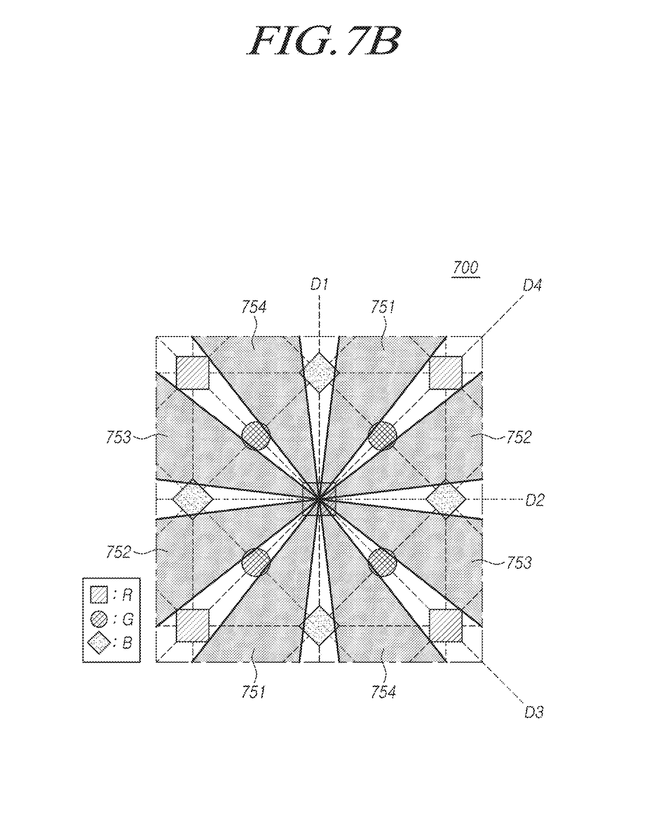

According to an embodiment, to minimize a moire phenomenon, the first pattern 40 may be disposed at an angle within a predetermined angle range inclined with respect to a pixel array in which the plurality of subpixels 600 are disposed in a predetermined direction (e.g., the first arrangement direction to the fourth arrangement direction D1, D2, D3, D4). For example, the first pattern 40 may be disposed inclined by 7° to 38° with respect to the pixel array. Due to an arrangement structure of the first pattern 40 disposed at a predetermined angle with respect to the pixel array, a moire phenomenon occurring in case that a period P2 where the plurality of subpixels are disposed and the first pattern 40 disposed at a first period P1 overlap under a predetermined condition may be decreased. This is described with reference to FIGS. 7A to 7B.

According to an embodiment, the first pattern 40 may extend in a direction substantially corresponding to a direction in which a folding axis (e.g., the folding axis F of FIG. 1) extends. As an example, the first pattern 40 having a predetermined shape may have a predetermined length in a direction parallel to a direction in which the folding axis F extends. The predetermined length may have a range of, e.g., 2 to 15 millimeter (mm), but the disclosure is not limited thereto.

According to an embodiment, in response to the flexible display 20 being turned off, the second region 520 in which the second pattern 50 is provided on the first layer 310 may be visually distinguished from the first region 510 in which the first pattern 40 is provided. As a result, in case that the flexible display 20 is turned off, the visual shape L may be displayed in the second region 520. As an example, in response to the flexible display 20 being turned off, a character "AAABBCCC" may be visible in the second region 520 of the folding cover region F. However, without being limited thereto, in response to the flexible display 20 being turned off, a visual shape L including various characters or logos may be visible in the second region 520.

According to an embodiment, the second pattern 50 may be disposed at the same period as a period P1 where the first pattern 40 is disposed or may be disposed at a different period to be visually distinguished from the first pattern 40. The second pattern 50 may also be disposed aperiodically. The second pattern 50 may have a regular shape or may have an irregular shape. The second pattern 50 may be disposed by combining a pattern having a regular shape and a pattern having an irregular shape. The second pattern 50 may include a main pattern and a sub pattern in contact with at least a portion of the main pattern. The second pattern 50 may extend from at least a portion of the first pattern 40. The shape or arrangement of the second pattern 50 is described with reference to FIGS. 8A to 8D.

FIG. 7A is an enlarged view illustrating a portion 700 of FIG. 6 according to an embodiment of the disclosure. In other words, FIG. 7A may be understood as an enlarged view for illustrating an angle that the first pattern 40 forms with a pixel array of at least one of the subpixels 501.

FIG. 7B is an enlarged view illustrating a portion of FIG. 6 according to an embodiment of the disclosure. FIG. 7B may be understood as a view illustrating a region in which a pattern structure (e.g., the first pattern 40 and the second pattern 50 of FIG. 5) included in the front cover 101 may be disposed to minimize a moire phenomenon.

Referring to FIG. 7A, according to an embodiment, to minimize a moire phenomenon, the first pattern 40 may be disposed at an angle within a predetermined angle range inclined with respect to a pixel array in which the plurality of subpixels 600 are disposed in a predetermined direction (e.g., the first arrangement direction to the fourth arrangement direction D1, D2, D3, D4). For example, the first pattern 40 may be disposed inclined by 7° to 38° with respect to the pixel array.

According to an embodiment, the first pattern 40 may form a predetermined angle with the third arrangement direction D3 closest among the first arrangement direction to the fourth arrangement direction D1, D2, D3, D4. The predetermined angle may have a range of, e.g., 7° to 38°.

Referring to FIG. 7B, for a pixel array in which a plurality of subpixels are disposed, a region in which the first pattern 40 may be disposed to minimize a moire phenomenon may be considered. FIG. 7B illustrates that the red subpixel R and the green subpixel G are disposed at a predetermined period (e.g., the second period P2 of FIG. 6) around the blue subpixel B, but may also be applied mutatis mutandis to a case in which the blue subpixel B and the green subpixel G are disposed around the red subpixel R and a case in which the red subpixel R and the blue subpixel B are disposed around the green subpixel G.

According to an embodiment, the moire phenomenon may be minimized in case that the first pattern 40 is disposed in a first region to a fourth region 751, 752, 753, 754. The first region to the fourth region 751, 752, 753, 754 may be a region located between at least two adjacent arrangement directions among the first arrangement direction to the fourth arrangement direction D1, D2, D3, D4.

According to an embodiment, the first region 751 may be located between the first arrangement direction D1 and the fourth arrangement direction D4. The first region 751 may be a region satisfying a predetermined angle from the first arrangement direction D1 and the fourth arrangement direction D4. The predetermined angle may have a range of, e.g., 7° to 38°.

According to an embodiment, the second region 752 may be located between the fourth arrangement direction D4 and the second arrangement direction D2. The second region 752 may be a region satisfying a predetermined angle from the fourth arrangement direction D4 and the second arrangement direction D2. The predetermined angle may have a range of, e.g., 7° to 38°.

According to an embodiment, the third region 753 may be located between the second arrangement direction D2 and the third arrangement direction D3. The third region 753 may be a region satisfying a predetermined angle from the second arrangement direction D2 and the third arrangement direction D3. The predetermined angle may have a range of, e.g., 7° to 38°.

According to an embodiment, the fourth region 754 may be located between the first arrangement direction D1 and the third arrangement direction D3. The fourth region 754 may be a region satisfying a predetermined angle from the first arrangement direction D1 and the third arrangement direction D3. The predetermined angle may have a range of, e.g., 7° to 38°.

FIGS. 8A, 8B, 8C, and 8D, are views illustrating a portion of a second pattern (e.g., the second pattern 50 of FIG. 5) included in a front cover (e.g., the front cover 101 of FIG. 1) according to various embodiments of the disclosure. In other words, FIGS. 8A to 8D may be understood as views illustrating an arrangement structure or shape of the second pattern 50 visually distinguishable from a first pattern (e.g., the first pattern 40 of FIG. 5) in response to a flexible display (e.g., the flexible display 20 of FIG. 4) being turned off.

Referring to FIGS. 8A to 8D, the second pattern 50 may include a main pattern 51 and a sub pattern 53. The main pattern 51 may correspond to at least a portion of the first pattern 40. As an example, the main pattern 51 may be substantially the same as the first pattern.

According to an embodiment, the main pattern 51 may have a predetermined period. The predetermined period may be, e.g., a first pitch P1 substantially the same as the first pattern 40. The predetermined period may be different from, e.g., the first pitch P1. The second pattern 50 may be disposed to be greater than the second pitch P2 where the plurality of subpixels (e.g., the subpixels 501 of FIG. 5) are disposed.

According to an embodiment, the sub pattern 53 may be disposed between main patterns 51 having a predetermined period. As an example, the sub pattern 53 may be alternately disposed with the main pattern 51.

According to an embodiment, the sub pattern 53 may extend from at least a portion of the main pattern 51. The sub pattern 53 may extend from at least a portion of the main pattern 51 in a predetermined direction. The predetermined direction may be, e.g., a direction forming a predetermined angle from the first arrangement direction to the fourth arrangement direction D1, D2, D3, D4 in which the plurality of subpixels 501 are disposed. The predetermined angle may have a range of, e.g., 7° to 38°.

According to an embodiment, the sub pattern 53 may have a regular shape or an irregular shape. The sub pattern 53 may be repeatedly disposed with the regular shape and the irregular shape at a predetermined period. The sub pattern 53 may also be aperiodically disposed with the regular shape and the irregular shape.

According to an embodiment, the first pattern 40 and the second pattern 50 may have a predetermined length. The first pattern 40 and the second pattern 50 may have, e.g., substantially a length of 2 mm to 15 mm in a direction in which the first pattern 40 and the second pattern 50 extend (e.g., the direction of the folding axis A). However, without being limited thereto, the first pattern 40 may be provided with various lengths to minimize a moire phenomenon, and the second pattern 50 may be provided with various lengths to minimize the moire phenomenon and to be visually distinguished from the first pattern 40.

Hereinafter, in FIGS. 8A to 8D, a manner in which the main pattern 51 and the sub pattern 53 are disposed or a shape of the sub pattern 53 is described.

Referring to FIG. 8A, a sub pattern 53a may be disposed between main patterns 51. In other words, the sub pattern 53a may be disposed between the main pattern 51 and another main pattern 51. The sub pattern 53a may be alternately disposed with the main pattern 51. The sub pattern 53a may have a relatively shorter length compared to the main pattern 51.

According to an embodiment, the sub pattern 53a may be located within a predetermined angle range from the first arrangement direction to the fourth arrangement direction D1, D2, D3, D4 in which the pixel array is disposed. The predetermined angle range may be, e.g., 7° to 38°.

Referring to FIG. 8B, a sub pattern 53b may extend from at least a portion of the main pattern 51 in a predetermined direction. The at least a portion of the main pattern 51 in which the sub pattern 53b is disposed may be arbitrarily determined. A predetermined direction in which the sub pattern 53b extends from at least a portion of the main pattern 51 may be located within a predetermined angle range from the first arrangement direction to the fourth arrangement direction D1, D2, D3, D4 in which the pixel array is disposed. The predetermined angle range may be, e.g., 7° to 38°.

Referring to FIG. 8C, a sub pattern 53c may be disposed between main patterns 51. In other words, the sub pattern 53c may be disposed between the main pattern 51 and another main pattern 51. The sub pattern 53c may be alternately disposed with the main pattern 51. As an example, the sub pattern 53c may not be present between the main pattern 51 and another main pattern 51.

According to an embodiment, the sub pattern 53c may have a different shape from the main pattern 51. The sub pattern 53c may have a relatively longer length than the main pattern 51.

Referring to FIG. 8D, a sub pattern 53d may be disposed between main patterns 51. In other words, the sub pattern 53d may be disposed between the main pattern 51 and another main pattern 51. The sub pattern 53d may have patterns of different shapes periodically disposed or aperiodically disposed. The sub pattern 53d may have patterns of irregular shapes periodically disposed or aperiodically disposed. As an example, the sub pattern 53d may include a first sub pattern 531d having a relatively longer length than the main pattern 51 and a second sub pattern 533d having a relatively shorter length than the main pattern 51.

Although not illustrated, the second pattern 50 may include a sub pattern 53 having various shapes. The sub pattern 53 may be implemented by combining at least two or more of the sub patterns 53a, 53b, 53c, 53d illustrated in FIGS. 8A to 8D.

FIGS. 9A, 9B, 9C and 9D are views illustrating a first layer (e.g., the first layer 310 of FIGS. 3A to 3C) including a first pattern (e.g., the first pattern 40 of FIG. 5) according to various embodiments of the disclosure. In other words, FIGS. 9A to 9D may be understood as views illustrating extended embodiments of various shapes that the first pattern 40 may have.

Referring to FIG. 9A, the first layer 310 may have a first pattern including a plurality of openings 901 (e.g., the plurality of openings 401 of FIG. 3A) or a plurality of recesses (e.g., the plurality of recesses 402, 403 of FIGS. 3B and 3C) of the same shape (e.g., a diamond shape). The first pattern may include a first sub pattern in which the plurality of openings 901 are disposed at a 3-1th pitch P31 in a first direction (e.g., the y-axis direction parallel to the folding axis A). The first pattern may include a second sub pattern in which the plurality of openings 901 are disposed at a 3-2th pitch P32 in a second direction perpendicular to the first direction.

According to an embodiment, to reduce a moire phenomenon due to an effect of light between the first layer 310 and the display panel 21 (e.g., the display panel 21 of FIG. 5), the plurality of red subpixels, the plurality of green subpixels, or the plurality of blue subpixels included in the display panel 21 may be disposed to provide (or form) a pattern disposed at a pitch smaller than the 3-1th pitch P31 in substantially the same direction as a direction in which the plurality of openings 901 included in the first sub pattern of the first layer 310 are disposed at the 3-1th pitch P31.

According to an embodiment, to reduce a moire phenomenon due to an effect of light between the first layer 310 and the display panel 21, the plurality of red subpixels, the plurality of green subpixels, or the plurality of blue subpixels included in the display panel 21 may be disposed to provide (or form) a pattern disposed at a pitch smaller than the 3-2th pitch P32 in substantially the same direction as a direction in which the plurality of openings 901 included in the second sub pattern of the first layer 310 are disposed at the 3-2th pitch P32.

According to an embodiment, to reduce a moire phenomenon due to an effect of light between the first layer 310 and the display panel 21, an edge of the plurality of openings 901 may be provided (or formed) not to be substantially parallel to arrangement directions regarding the plurality of subpixels included in the display panel 21 (e.g., the first arrangement direction D1, the second arrangement direction D2, the third arrangement direction D3, and the fourth arrangement direction D4 of FIG. 6). As an example, the edge of the plurality of openings 901 may form a predetermined angle with the first arrangement direction to the fourth arrangement direction D1, D2, D3, D4. The predetermined angle may have a range of, e.g., 7° to 38°.

Referring to FIG. 9B, a fourth pattern of the first layer 310 may include a first sub pattern in which a plurality of first openings 911 of a first shape are disposed at a 4-1th pitch P41 in a first direction (e.g., the x-axis direction perpendicular to the folding axis A). The fourth pattern of the first layer 310 may include a second sub pattern in which a plurality of second openings 912 of a second shape are disposed at a 4-2th pitch P42 in the first direction. The fourth pattern of the first layer 310 may include a third sub pattern in which a plurality of third openings 913 of a third shape are disposed at a 4-3th pitch P43 in the first direction. The fourth pattern of the first layer 310 may include a fourth sub pattern in which the plurality of first openings 911 of the first shape are disposed at a 4-4th pitch P44 in a second direction perpendicular to the first direction (e.g., the y-axis direction parallel to the folding axis A). The fourth pattern of the first layer 310 may include a fifth sub pattern in which the plurality of second openings 912 of the second shape are disposed at a 4-5th pitch P45 in the second direction perpendicular to the first direction. The fourth pattern of the first layer 310 may include a sixth sub pattern in which the plurality of third openings 913 of the third shape are disposed at a 4-6th pitch P46 in the second direction perpendicular to the first direction.

According to an embodiment, to reduce a moire phenomenon due to an effect of light between the first layer 310 and the display panel 21, the plurality of red subpixels, the plurality of green subpixels, or the plurality of blue subpixels included in the display panel 21 may be disposed to provide (or form) a pattern disposed at a pitch smaller than the 4-1th pitch P41 in substantially the same direction as a direction in which the plurality of first openings 911 included in the first sub pattern of the first layer 310 are disposed at the 4-1th pitch P41.

According to an embodiment, to reduce a moire phenomenon due to an effect of light between the first layer 310 and the display panel 21, the plurality of red subpixels, the plurality of green subpixels, or the plurality of blue subpixels included in the display panel 21 may be disposed to provide (or form) a pattern disposed at a pitch smaller than the 4-2th pitch P42 in substantially the same direction as a direction in which the plurality of second openings 912 included in the second sub pattern of the first layer 310 are disposed at the 4-2th pitch P42.

According to an embodiment, to reduce a moire phenomenon due to an effect of light between the first layer 310 and the display panel 21, the plurality of red subpixels, the plurality of green subpixels, or the plurality of blue subpixels included in the display panel 21 may be disposed to provide (or form) a pattern disposed at a pitch smaller than the 4-3th pitch P43 in substantially the same direction as a direction in which the plurality of third openings 913 included in the third sub pattern of the first layer 310 are disposed at the 4-3th pitch P43.

According to an embodiment, to reduce a moire phenomenon due to an effect of light between the first layer 310 and the display panel 21, the plurality of red subpixels, the plurality of green subpixels, or the plurality of blue subpixels included in the display panel 21 may be disposed to provide (or form) a pattern disposed at a pitch smaller than a tenth pitch P10 in substantially the same direction as a direction in which the plurality of first openings 911 included in the fourth sub pattern of the first layer 310 are disposed at the tenth pitch P10.

According to an embodiment, to reduce a moire phenomenon due to an effect of light between the first layer 310 and the display panel 21, the plurality of red subpixels, the plurality of green subpixels, or the plurality of blue subpixels included in the display panel 21 may be disposed to provide (or form) a pattern disposed at a pitch smaller than the 4-5th pitch P45 in substantially the same direction as a direction in which the plurality of second openings 912 included in the fifth sub pattern of the first layer 310 are disposed at the 4-5th pitch P45.

According to an embodiment, to reduce a moire phenomenon due to an effect of light between the first layer 310 and the display panel 21, the plurality of red subpixels, the plurality of green subpixels, or the plurality of blue subpixels included in the display panel 21 may be disposed to provide (or form) a pattern disposed at a pitch smaller than the 4-6th pitch P46 in substantially the same direction as a direction in which the plurality of third openings 913 included in the sixth sub pattern of the first layer 310 are disposed at the 4-6th pitch P46.

According to an embodiment, to reduce a moire phenomenon due to an effect of light between the first layer 310 and the display panel 21, an edge of the plurality of first openings 911, an edge of the plurality of second openings 912, and an edge of the plurality of third openings 913 may be provided (or formed) not to be substantially parallel to arrangement directions regarding the plurality of subpixels included in the display panel 21 (e.g., the first arrangement direction D1, the second arrangement direction D2, the third arrangement direction D3, and the fourth arrangement direction D4 of FIG. 8). As an example, the edge of the plurality of first openings 911, the edge of the plurality of second openings 912, and the edge of the plurality of third openings 913 may form a predetermined angle with the first arrangement direction to the fourth arrangement direction D1, D2, D3, D4. The predetermined angle may have a range of, e.g., 7° to 38°.

Referring to FIG. 9C, the first layer 310 may have a first pattern including a plurality of openings 921 (e.g., the plurality of openings 401 of FIG. 3A) or a plurality of recesses (e.g., the plurality of recesses 402, 403 of FIGS. 3B and 3C) of the same shape (e.g., a "W" shape). The first pattern may include a first sub pattern in which the plurality of openings 921 are disposed at a 5-1th pitch P51 in a first direction (e.g., the y-axis direction parallel to the folding axis A). The first pattern may include a second sub pattern in which the plurality of openings 901 are disposed at a 5-2th pitch P52 in a second direction perpendicular to the first direction.

According to an embodiment, to reduce a moire phenomenon due to an effect of light between the first layer 310 and the display panel 21 (e.g., the display panel 21 of FIG. 5), the plurality of red subpixels, the plurality of green subpixels, or the plurality of blue subpixels included in the display panel 21 may be disposed to provide (or form) a pattern disposed at a pitch smaller than the 5-1th pitch P51 in substantially the same direction as a direction in which the plurality of openings 901 included in the first sub pattern of the first layer 310 are disposed at the 5-1th pitch P51.

According to an embodiment, to reduce a moire phenomenon due to an effect of light between the first layer 310 and the display panel 21, the plurality of red subpixels, the plurality of green subpixels, or the plurality of blue subpixels included in the display panel 21 may be disposed to provide (or form) a pattern disposed at a pitch smaller than the 5-2th pitch P52 in substantially the same direction as a direction in which the plurality of openings 921 included in the second sub pattern of the first layer 310 are disposed at the 5-2th pitch P52.

According to an embodiment, to reduce a moire phenomenon due to an effect of light between the first layer 310 and the display panel 21, an edge of the plurality of openings 921 may be provided (or formed) not to be substantially parallel to arrangement directions regarding the plurality of subpixels included in the display panel 21 (e.g., the first arrangement direction D1, the second arrangement direction D2, the third arrangement direction D3, and the fourth arrangement direction D4 of FIG. 6). As an example, the edge of the plurality of openings 921 may form a predetermined angle with the first arrangement direction to the fourth arrangement direction D1, D2, D3, D4. The predetermined angle may have a range of, e.g., 7° to 38°.

Referring to FIG. 9D, the first layer 310 may have a first pattern including a plurality of openings 931 (e.g., the plurality of openings 401 of FIG. 3A) or a plurality of recesses (e.g., the plurality of recesses 402, 403 of FIGS. 3B and 3C) of the same shape (e.g., a continuous "W" shape). The first pattern may include a first sub pattern in which the plurality of openings 931 are disposed at a 6-1th pitch P61 in a first direction (e.g., the y-axis direction parallel to the folding axis A). The first pattern may include a second sub pattern in which the plurality of openings 901 are disposed at a 6-2th pitch P62 in a second direction perpendicular to the first direction.

According to an embodiment, as the first pattern extends in the first direction, a width in the second direction may change. As an example, the first pattern may have a width in the second direction alternately widening and narrowing.

According to an embodiment, to reduce a moire phenomenon due to an effect of light between the first layer 310 and the display panel 21 (e.g., the display panel 21 of FIG. 5), the plurality of red subpixels, the plurality of green subpixels, or the plurality of blue subpixels included in the display panel 21 may be disposed to provide (or form) a pattern disposed at a pitch smaller than the 6-1th pitch P61 in substantially the same direction as a direction in which the plurality of openings 901 included in the first sub pattern of the first layer 310 are disposed at the 6-1th pitch P61.

According to an embodiment, to reduce a moire phenomenon due to an effect of light between the first layer 310 and the display panel 21, the plurality of red subpixels, the plurality of green subpixels, or the plurality of blue subpixels included in the display panel 21 may be disposed to provide (or form) a pattern disposed at a pitch smaller than the 5-2th pitch P52 in substantially the same direction as a direction in which the plurality of openings 921 included in the second sub pattern of the first layer 310 are disposed at the 6-2th pitch P62.

According to an embodiment, to reduce a moire phenomenon due to an effect of light between the first layer 310 and the display panel 21, an edge of the plurality of openings 921 may be provided (or formed) not to be substantially parallel to arrangement directions regarding the plurality of subpixels included in the display panel 21 (e.g., the first arrangement direction D1, the second arrangement direction D2, the third arrangement direction D3, and the fourth arrangement direction D4 of FIG. 6). As an example, the edge of the plurality of openings 921 may form a predetermined angle with the first arrangement direction to the fourth arrangement direction D1, D2, D3, D4. The predetermined angle may have a range of, e.g., 7° to 38°.

Further, the first pattern 40 included in the first layer 310 may be implemented in other various forms that may reduce a moire phenomenon due to an effect of light between the first layer 310 and the display panel 21 while securing flexibility.

A flexible display 20 according to an embodiment of the disclosure may include a display panel 21 including a pixel array in which a plurality of subpixels 501 outputting light of the same wavelength are disposed at a predetermined period P2 and a front cover 101 disposed on one surface of the display panel 21. The front cover 101 may include a glass member 310 having a first pattern 40 formed by a plurality of openings 401 or recesses 402, 403 formed corresponding to a variable region F and disposed at a predetermined period P1. The first pattern 40 may form an angle of 7 degrees to 38 degrees with respect to the pixel array.

In the flexible display 20 according to an embodiment of the disclosure, the first pattern 40 may include a second pattern 50. The second pattern 50 may be visually distinguishable from the first pattern in response to the display panel 21 being turned off.

In the flexible display 20 according to an embodiment of the disclosure, a visual shape L formed by the second pattern 50 may be provided on at least a portion of the variable region F.

In the flexible display 20 according to an embodiment of the disclosure, the second pattern 50 may include a main pattern 51 disposed at the same period as the first pattern 40 or disposed at a different period.

In the flexible display 20 according to an embodiment of the disclosure, the second pattern 50 may include a sub pattern 53 having a regular or irregular shape.

In the flexible display 20 according to an embodiment of the disclosure, the sub pattern 53b may extend from at least a portion of the main pattern 51.

In the flexible display 20 according to an embodiment of the disclosure, a distance P2 between two adjacent pixels among the plurality of subpixels 501 may be relatively shorter than a distance P1 between two adjacent ones among the plurality of openings 401 or recesses 402, 403.

In the flexible display 20 according to an embodiment of the disclosure, the first pattern 40 may be disposed in a direction of a folding axis A of the variable region F.

In the flexible display 20 according to an embodiment of the disclosure, the first pattern 40 may have a length of 2 mm to 15 mm.

In the flexible display 20 according to an embodiment of the disclosure, the glass member 310 may have a thickness of 50 um (micrometer) to 500 um.

The flexible display 20 according to an embodiment of the disclosure may include an adhesive member provided in the plurality of openings 401 or the plurality of recesses 402, 403 and having a predetermined refractive index and a predetermined modulus value.

In the flexible display 20 according to an embodiment of the disclosure, the predetermined refractive index may be 1.48 to 1.55, and the predetermined modulus value may be 0.01 MPa to 1 GPa.

An electronic device 1 according to an embodiment of the disclosure may include a foldable housing 10 providing a front surface 10A of the electronic device 1 and a rear surface 10B of the electronic device 1 and a flexible display 20 located in an inner space of the foldable housing 10, coupled with a front cover 101 providing the front surface 10A among the foldable housing, and visible through the front cover 101. The flexible display 20 may include a pixel array in which a plurality of subpixels 501 outputting light of the same wavelength are disposed at a predetermined period P2. The front cover 101 may include a glass member 310 having a first pattern 40 formed by a plurality of openings 401 or recesses 402, 403 formed corresponding to a variable region F and disposed at a predetermined period P1. The first pattern 40 may form an angle of 7 degrees to 38 degrees with respect to the pixel array.

In the electronic device 1 according to an embodiment of the disclosure, the first pattern 40 may include a second pattern 50, and the second pattern 50 may be visually distinguishable from the first pattern 40 in response to the display panel being turned off.

In the electronic device 1 according to an embodiment of the disclosure, a visual shape L formed by the second pattern 50 may be provided on at least a portion of the variable region F.

In the electronic device 1 according to an embodiment of the disclosure, the second pattern may include a main pattern 51 disposed at the same period as the first pattern or disposed at a different period.

In the electronic device 1 according to an embodiment of the disclosure, the second pattern 50 may include a sub pattern 53 having a regular or irregular shape.

In the electronic device 1 according to an embodiment of the disclosure, the sub pattern 53b may extend from at least a portion of the main pattern 51.

In the electronic device 1 according to an embodiment of the disclosure, the foldable housing 10 may be foldable such that the front surface 10A is folded inward with respect to a folding axis A.

In the electronic device 1 according to an embodiment of the disclosure, the foldable housing 10 may be foldable such that the front surface 10A is folded outward with respect to a folding axis A.

The electronic device according to various embodiments of the disclosure may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. As used herein, each of such phrases as "A or B," "at least one of A and B," “at least one of A or B,” "A, B, or C," "at least one of A, B, and C," and “at least one of A, B, or C,” may include all possible combinations of the items enumerated together in a corresponding one of the phrases. As used herein, such terms as "1st" and "2nd," or “first” and "second" may be used to simply distinguish a corresponding component from another, and does not limit the components in other aspect (e.g., importance or order). It is to be understood that if an element (e.g., a first element) is referred to, with or without the term “operatively” or “communicatively,” as “coupled with,” "coupled to," "connected with," or “connected to” another element (e.g., a second element), it means that the element may be coupled with the other element directly (e.g., wiredly), wirelessly, or via a third element.

As used herein, the term "module" may include a unit implemented in hardware, software, or firmware, and may interchangeably be used with other terms, for example, "logic," "logic block," "part," or "circuitry." A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 1). For example, a processor (e.g., the processor 120) of the machine (e.g., the electronic device 1) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The storage medium readable by the machine may be provided in the form of a non-transitory storage medium. Wherein, the term "non-transitory" simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store^{TM}), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. Some of the plurality of entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

1. A flexible display, comprising:
a display panel including a pixel array in which a plurality of subpixels outputting light of the same wavelength are disposed at a predetermined period; and
a front cover disposed on one surface of the display panel,
wherein the front cover includes a glass member having a first pattern formed by a plurality of openings or recesses formed corresponding to a variable region and disposed at a predetermined period, and
wherein the first pattern forms an angle of 7 degrees to 38 degrees with respect to the pixel array.

2. The flexible display of claim 1,
wherein the first pattern includes a second pattern, and
wherein the second pattern is visually distinguishable from the first pattern in response to the display panel being turned off.

3. The flexible display of claim 2, wherein the flexible display provides a visual shape formed by the second pattern on at least a portion of the variable region.

4. The flexible display of claim 2, wherein the second pattern includes a main pattern disposed at the same period as the first pattern or disposed at a different period.

5. The flexible display of claim 4, wherein the second pattern includes a sub pattern having a regular or irregular shape.

6. The flexible display of claim 5, wherein the sub pattern extends from at least a portion of the main pattern.

7. The flexible display of claim 2, wherein a distance between two adjacent pixels among the plurality of subpixels is relatively shorter than a distance between two adjacent ones among the plurality of openings or recesses.

8. The flexible display of claim 1, wherein the first pattern is disposed in a direction of a folding axis of the variable region.

9. The flexible display of claim 1, wherein the first pattern has a length of 2 mm to 15 mm.

10. The flexible display of claim 1, wherein the glass member has a thickness of 50 um (micrometer) to 500 um.

11. The flexible display of claim 1, comprising an adhesive member provided in the plurality of openings or the plurality of recesses and having a predetermined refractive index and a predetermined modulus value.

12. The flexible display of claim 11,
wherein the predetermined refractive index is 1.48 to 1.55, and
wherein the predetermined modulus value is 0.01 MPa to 1 GPa.

13. An electronic device, comprising:
a foldable housing providing a front surface of the electronic device and a rear surface of the electronic device; and
a flexible display located in an inner space of the foldable housing, coupled with a front cover providing the front surface of the foldable housing, and visible through the front cover,
wherein the flexible display comprises a display panel including a pixel array in which a plurality of subpixels outputting light of the same wavelength are disposed at a predetermined period,
wherein the front cover includes a glass member having a first pattern formed by a plurality of openings or recesses formed corresponding to a variable region and disposed at a predetermined period, and
wherein the first pattern forms an angle of 7 degrees to 38 degrees with respect to the pixel array.

14. The electronic device of claim 13,
wherein the first pattern includes a second pattern, and
wherein the second pattern is visually distinguishable from the first pattern in response to the display panel being turned off.

15. The electronic device of claim 14, wherein the electronic device provides a visual shape formed by the second pattern on at least a portion of the variable region.

16. The electronic device of claim 14, wherein the second pattern includes a main pattern disposed at the same period as the first pattern or disposed at a different period.

17. The electronic device of claim 16, wherein the second pattern includes a sub pattern having a regular or irregular shape.

18. The electronic device of claim 17, wherein the sub pattern extends from at least a portion of the main pattern.

19. The electronic device of claim 14, wherein a distance between two adjacent pixels among the plurality of subpixels is relatively shorter than a distance between two adjacent ones among the plurality of openings or recesses.

20. The electronic device of claim 13, wherein the first pattern is disposed in a direction of a folding axis of the variable region.
